(19) United States
(12) Patent Application Publication
(10) Pub. No.: US 2015/0194555 A1
(43) Pub. Date: Jul. 9, 2015

(54) PACKAGED LUMINESCENT SOLAR CONCENTRATOR PANEL FOR PROVIDING HIGH EFFICIENCY LOW COST SOLAR HARVESTING

(71) Applicant: NITTO DENKO CORPORATION, Osaka (JP)

(72) Inventors: Hongxi Zhang, Temecula, CA (US); Weiping Lin, Carlsbad, CA (US); Michiharu Yamamoto, Carlsbad, CA (US)

(21) Appl. No.: 14/585,642

(22) Filed: Dec. 30, 2014

Related U.S. Application Data
(60) Provisional application No. 61/923,547, filed on Jan. 3, 2014.

(51) Int. Cl. H01L 31/055; H02S 40/22

(52) U.S. Cl. CPC H01L 31/055; H02S 40/22

(57) ABSTRACT

Described herein are packaged luminescent solar concentrator panels. Some embodiments comprise a photovoltaic device (e.g a solar cell), a luminescent solar concentrator, and a rigid base. The packaged luminescent solar concentrator forms a rigid structure. A frame may be used to engage the at least one photovoltaic device. The luminescent solar concentrator device can comprise a planar layer that acts to absorb photons. The packaged luminescent solar concentrator panel collects both direct and diffuse light and provides highly efficient and low cost solar harvesting solutions by using a minimal amount of expensive solar cells. The packaged luminescent solar concentrator panel is well suited for building integrated photovoltaics such as sunroofs, skylights, windows, and facades of commercial and residential buildings.

### CROSS-REFERENCE TO RELATED APPLICATIONS

The present application claims the benefit of priority to U.S. Patent Application No. 61/923,547, filed Jan. 3, 2014, the entirety of which is hereby incorporated by reference herein.

### BACKGROUND OF THE INVENTION

1. Field of the Invention

The present disclosure generally relates to devices for improving solar harvesting. By using these devices solar harvesting efficiency can be improved.

2. Description of the Related Art

The utilization of solar energy offers a promising alternative energy source to the traditional fossil fuels, and therefore, the development of devices that can convert solar energy into electricity, such as photovoltaic devices (e.g., solar cells), has drawn significant attention in recent years.

### SUMMARY OF THE INVENTION

The present disclosure provides a packaged luminescent solar concentrator panel.

Some embodiments pertain to a packaged luminescent solar concentrator panel comprising a luminescent solar concentrator configured to receive photons from a photon source and a rigid base disposed over a portion of the luminescent solar concentrator, the rigid base configured to insert into a rigid frame to provide a support for the luminescent solar concentrator. In some embodiments, the luminescent solar concentrator comprises a wavelength conversion layer, the wavelength conversion layer comprising at least one chromophore.

Some embodiments, pertain to a packaged luminescent solar concentrator panel comprising a luminescent solar concentrator configured to receive photons from a photon source. In some embodiments, the luminescent solar concentrator comprises a wavelength conversion layer comprising at least one chromophore. In some embodiments, the luminescent solar concentrator comprises an edge surface. In some embodiments, the packaged luminescent solar concentrator panel comprises a rigid base disposed over an edge surface of the luminescent solar concentrator. In some embodiments, the rigid base configured to provide support for the luminescent solar concentrator.

In some embodiments, the luminescent solar concentrator device comprises four edge surfaces, a top surface for receipt of the photons, and a bottom surface, wherein the top surface is closer to the photon source than the bottom surface.

In some embodiments, the packaged luminescent concentrator panel, further comprises at least one photovoltaic device disposed between the wavelength conversion layer and the rigid base. In some embodiments, the at least one photovoltaic device is mounted to an edge surface of the luminescent solar concentrator device.

In some embodiments, the at least one photovoltaic device is mounted to the bottom surface of the luminescent solar concentrator device.

In some embodiments, the at least one photovoltaic device is mounted to the bottom surface of the luminescent solar concentrator device and one or more additional photovoltaic devices are mounted to an edge of the luminescent solar concentrator device.

In some embodiments, the at least one photovoltaic device is mounted to the rigid base with an adhesive. In some embodiments, the adhesive is a thermally conductive adhesive. In some embodiments, the thermally conductive adhesive is a tape or a film. In some embodiments, the thermally conductive adhesive has a thermal conductivity of about 1 W/mK or greater.

In some embodiments, the luminescent solar concentrator is mounted to the at least one photovoltaic device using a transparent adhesive. In some embodiments, the transparent adhesive is a tape or a film comprising an acrylic polymer, polyethylene terephthalate, polymethyl methacrylate, polyvinyl butyral, ethylene vinyl acetate polymer, ethylene tetrafluoroethylene polymer, polyimide, amorphous polycarbonate, polystyrene, a siloxane sol-gel, polyurethane, polyacrylate, or combinations thereof.

In some embodiments, the rigid base comprises a metal, metal composite, metal alloy, ceramic, plastic material, or combinations thereof. In some embodiments, the rigid base comprises aluminum, tin, bronze, steel, iron, copper, or any combination thereof.

In some embodiments, the packaged luminescent solar concentrator panel further comprising a frame configured to encapsulate the rigid base. In some embodiments, the frame is a two-sided frame configured to engage two luminescent solar concentrator panels, and wherein the frame is configured to encapsulate the rigid base.

In some embodiments, the frame encapsulates each edge surface of the luminescent solar concentrator panel, forming the perimeter of the luminescent solar concentrator panel.

In some embodiments, the frame encapsulates at least a portion of the luminescent solar concentrator and is sealed using a low refractive index adhesive, wherein the low refractive index adhesive fills a gap between the luminescent solar concentrator and the frame. In some embodiments, the low refractive index adhesive comprises a fluorinated polymer material.

In some embodiments, the frame comprises metal, metal composite, metal alloy, polymer, wood, or any combination thereof. In some embodiments, the frame comprises aluminum, tin, bronze, steel, iron, copper, or any combination thereof.

In some embodiments, the packaged luminescent solar concentrator panel further comprises a conduit in communication to the at least one photovoltaic device, wherein the conduit is configured to transport electricity away from the photovoltaic device.

In some embodiments, the luminescent solar concentrator further comprises glass or polymer plates. In some embodiments, the glass or polymer plates are configured to protect the wavelength conversion layer from the environment. In some embodiments, the glass or polymer plates are configured to internally reflect and refract a portion of the photons towards the photovoltaic device.

In some embodiments, the packaged luminescent solar concentrator panel's luminescent solar concentrator comprises a plurality of wavelength conversion layers. In some embodiments, each of the wavelength conversion layers absorbs photons at a different wavelength range. In some embodiments, each of the wavelength conversion layers comprises a different chromophore. In some embodiments, the wavelength conversion layers are positioned in descending order according to their absorption wavelength, such that short wavelength photons are absorbed in the top wavelength conversion layers, while longer wavelength photons are absorbed in the bottom wavelength conversion layers, wherein the top wavelength conversion layers are closest to the photon source and the bottom wavelength conversion layer is farthest from the photon source.

In some embodiments, the wavelength conversion layer comprises a polymer matrix. In some embodiments, the polymer matrix of the wavelength conversion layer comprises a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof. In some embodiments, the polymer matrix may be made of one host polymer, a host polymer and a co-polymer, or multiple polymers. In some embodiments, the refractive index of the polymer matrix material is in the range of about 1.40 to about 1.70.

In some embodiments, the wavelength conversion layer comprises a plurality of organic photostable chromophore compounds. In some embodiments, the at least one chromophore is present in the polymer matrix in an amount in the range of about 0.01 wt % to about 10.0 wt %. In some embodiments, the at least one chromophore is present in the polymer matrix in an amount in the range of about 0.1 wt % to about 1.0 wt %.

In some embodiments, the at least one chromophore is a down-shifting chromophore. In some embodiments, the at least one chromophore is a perylene derivative dye, benzotriazole derivative dye, benzothiadiazole derivative dye, or a combination thereof.

In some embodiments, the packaged luminescent solar concentrator panel further comprises at least one sensitizer. In some embodiments, the packaged luminescent solar concentrator panel further comprises at least one plasticizer. In some embodiments, the packaged luminescent solar concentrator panel further comprises a UV stabilizer, antioxidant, or absorber.

In some embodiments, the thickness of the wavelength conversion layer ranges from about 0.1 micron to about 1 mm, or about 0.5 micron to about 0.5 mm.

In some embodiments, multiple types of photovoltaic devices are used within the module and are independently selected and mounted to the surface of the luminescent solar concentrator device according to the emission wavelength of the wavelength conversion layer.

In some embodiments, at least one photovoltaic device comprises a Cadmium Sulfide/Cadmium Telluride solar cell, a Copper Indium Gallium Diselenide solar cell, an amorphous Silicon solar cell, a microcrystalline Silicon solar cell, a crystalline Silicon solar cell, or any combination thereof.

In some embodiments, the packaged luminescent solar concentrator panel comprises at least one solar cell or photovoltaic device, a luminescent solar concentrator device, and a rigid base (e.g., a rigid strip or support member). In some embodiments, the at least one solar cell is laminated to the rigid base using a thermally conductive adhesive, the edge of the luminescent solar concentrator device is mounted to the at least one solar cell using highly transparent adhesive. In some embodiments, a frame may be used to encapsulate the solar cell, and low refractive index adhesives are used to seal the gap between the luminescent solar concentrator device and the frame. In some embodiments, the luminescent solar concentrator device comprises at least one planar layer and at least one wavelength conversion layer, wherein the at least one planar layer and the at least one wavelength conversion layer may or may not be the same layer. In some embodiments the at least one planar layer having a major top surface for receipt of incident solar radiation, a bottom surface, and at least one edge surface through which radiation can escape. In some embodiments, the wavelength conversion layer comprises a polymer, sol-gel, or glass film doped with luminescent dyes. In some embodiments, the wavelength conversion layer comprises a polymer matrix and at least one organic photostable chromophore, wherein the at least one organic photostable chromophore acts to absorb incident photons of a particular wavelength range, and re-emit those photons at a different wavelength, wherein the re-emitted photons are internally reflected and refracted within the luminescent solar concentrator until they reach the edge surface where they may then pass through the highly transparent adhesive and into the at least one solar cell for conversion into electricity. The packaged luminescent solar concentrator panel collects both direct and diffuse light and provides highly efficient and low cost solar harvesting solutions by using a minimal amount of expensive solar cells. The packaged luminescent solar concentrator panel is well suited for building integrated photovoltaics such as sunroofs, skylights, and facades of commercial and residential buildings.

The packaged luminescent solar concentrator panel may have a variety of structures. In some embodiments, the packaged luminescent solar concentrator panel comprises a single luminescent solar concentrator device with the rigid base wrapped solely around the outside edges of the panel to form a rigid structure. In some embodiments the packaged luminescent solar concentrator panel comprises a single luminescent solar concentrator device with a frame encapsulation which is wrapped solely around the outside edges of the panel. In some embodiments, the packaged luminescent solar concentrator panel comprises multiple luminescent solar concentrator devices which are mounted into a single panel using multiple two sided frames. In some embodiments the packaged luminescent solar concentrator panel comprises solar cells which are mounted to a portion of the back of the major planar surface, wherein the rigid base is mounted to the solar cells to form a rigid structure.

In some embodiments, of the packaged luminescent solar concentrator panel the rigid base comprises metal, metal composite (e.g. a metal and a non-metal species), metal alloy, polymer, or any combination thereof. In some embodiments, the rigid base comprises a material selected from aluminum, tin, bronze, steel, iron, copper, or any combination thereof.

In some embodiments, the packaged luminescent solar concentrator panel further comprises a frame, which encapsulates the solar cell, wherein a low refractive index adhesive is used to seal the gap between the frame and the luminescent solar concentrator. In some embodiments of the packaged luminescent solar concentrator panel the frame comprises metal, metal composite (e.g. a metal and a non-metal species), metal alloy, polymer, wood, or any combination thereof. In some embodiments, the frame comprises a material selected from aluminum, tin, bronze, steel, iron, copper, or any combination thereof.

In some embodiments, a packaged luminescent solar concentrator panel comprising at least one wavelength conversion layer is provided. In some embodiments, the wavelength conversion layer may comprise at least one chromophore, wherein the chromophore is doped into a polymer matrix, sol-gel, or glass film. In some embodiments, said wavelength conversion layer comprises at least one chromophore and an optically transparent polymer matrix, and wherein the wavelength conversion layer receives as input at least one photon having a first wavelength, and provides as output at least one photon having a second wavelength which is different than the first. By employing the wavelength conversion layer in the luminescent solar concentrator, a new type of optical light collection system, fluorescence-based solar collectors, fluorescence-activated displays, and single-molecule spectroscopy can be provided.

In some embodiments, a luminescent solar concentrator may include several layers. For example, the packaged luminescent solar concentrator panel may comprise additional non-wavelength converting portions (e.g. glass or polymer layers without chromophores), which encapsulate the panel or a wavelength conversion layer of the luminescent solar concentrator. The glass or polymer layers may be designed to protect and prevent oxygen and moisture penetration into the panel's solar cells or into the wavelength conversion film. In some embodiments, the glass or polymer layers may be used as part of the luminescent solar concentrator to internally refract and/or reflect photons that are emitted from the wavelength conversion layer(s) in a direction that is towards the at least one photovoltaic device or solar cell. In some embodiments, the luminescent solar concentrator may further comprise additional polymer layers, or additional components within the polymer layers or wavelength conversion layer(s) such as sensitizers, plasticizers, UV absorbers, and/or other components which may improve efficiency or stability.

The packaged luminescent solar concentrator panel may comprise various photovoltaic devices or solar cells. In some embodiments, the packaged luminescent solar concentrator panel comprises at least one solar cell or photovoltaic device selected from the group consisting of a silicon based device, a III-V or II-VI junction device, a Copper-Indium-Gallium-Selenium (CIGS) thin film device, an organic sensitizer device, an organic thin film device, or a Cadmium Sulfide/Cadmium Telluride (CdS/CdTe) thin film device. In some embodiments, the packaged luminescent solar concentrator panel comprises multiple types of solar cells or photovoltaic devices.

The packaged luminescent solar concentrator panel may be provided in various lengths and widths so as to accommodate different sizes and types of applications, such as windows, building materials, etc.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the embodiments which follow.

### BRIEF DESCRIPTION OF THE DRAWINGS

FIG. 1 illustrates an embodiment of a solar cell panel and a rigid base.

FIG. 2 illustrates a luminescent solar concentrator mounting rack used to mount the edge of the luminescent solar concentrator to the rigid base/solar cell assembly using a transparent adhesive.

FIG. 3 illustrates an embodiment of a packaged luminescent solar concentrator panel comprising a single luminescent solar concentrator mounted into a frame which is wrapped around the outside edges of the luminescent solar concentrator.

FIG. 4 illustrates an embodiment of a packaged luminescent solar concentrator panel comprising multiple luminescent solar concentrators mounted into multiple two sided frames.

FIG. 5 illustrates an embodiment of a packaged luminescent solar concentrator panel comprising a luminescent solar concentrator with a single planar layer that is a wavelength conversion layer, and the luminescent solar concentrator is mounted onto a rigid base/solar cell assembly to form a rigid structure.

FIG. 6 illustrates an embodiment of a packaged luminescent solar concentrator panel comprising a luminescent solar concentrator, wherein the luminescent solar concentrator comprises a glass or polymer layer on top of a wavelength conversion layer, and the luminescent solar concentrator is mounted onto a rigid base/solar cell assembly to form a rigid structure.

FIG. 7 illustrates an embodiment of a packaged luminescent solar concentrator panel comprising a luminescent solar concentrator, wherein the luminescent solar concentrator comprises multiple glass or polymer layers and a wavelength conversion layer, and the luminescent solar concentrator is mounted onto a rigid base/solar cell assembly to form a rigid structure.

FIG. 8 illustrates an embodiment of a packaged luminescent solar concentrator panel comprising a luminescent solar concentrator, wherein the luminescent solar concentrator comprises multiple glass or polymer layers and a wavelength conversion layer, and the rigid base/solar cell assembly are mounted onto the luminescent solar concentrator on the edge of the major planar surface to form a rigid structure, with the corner ground and polished at an angle of about 30 to about 60 degrees, and a mirror surface is applied to reflect the photons into the solar cell.

FIG. 9 illustrates an embodiment of a large area packaged luminescent solar concentrator panel comprising a luminescent solar concentrator, wherein the luminescent solar concentrator comprises multiple glass or polymer layers and a wavelength conversion layer, and at least one rigid base/solar cell assembly are mounted onto the luminescent solar concentrator on the back of the major planar surface to form a rigid structure.

FIG. 10 illustrates an embodiment of a large area packaged luminescent solar concentrator panel comprising a luminescent solar concentrator, wherein the luminescent solar concentrator comprises multiple glass or polymer layers and a wavelength conversion layer, and rigid base/solar cell assemblies are mounted onto the luminescent solar concentrator on both the back of the major planar surface and the edge surface to form a rigid structure.

FIG. 11 illustrates an embodiment of a packaged luminescent solar concentrator panel comprising a luminescent solar concentrator, wherein the luminescent solar concentrator comprises a single planar layer of glass or polymer and one wavelength conversion layer, and a rigid base/solar cell assembly is mounted onto the luminescent solar concentrator on the edge surface to form a rigid structure.

FIG. 12 illustrates an embodiment of a packaged luminescent solar concentrator panel comprising a luminescent solar concentrator with a single planar layer that is a wavelength conversion layer, and the luminescent solar concentrator is mounted onto a rigid base/solar cell assembly to form a rigid structure, with a frame encapsulation to prevent moisture ingress.

FIG. 13 illustrates an embodiment of a packaged luminescent solar concentrator panel comprising a luminescent solar concentrator with dual planar layers that are wavelength conversion layers, and the luminescent solar concentrator is mounted onto a rigid base/solar cell assemblies to form a rigid structure, with a frame encapsulation to prevent moisture ingress.

FIG. 14 illustrates an embodiment of a packaged luminescent solar concentrator panel comprising a luminescent solar concentrator with multiple planar layers that are wavelength conversion layers, and the luminescent solar concentrator is mounted onto rigid base/solar cell assemblies to form a rigid structure, with a frame encapsulation to prevent moisture ingress.

FIG. 15 illustrates an embodiment of a packaged luminescent solar concentrator panel comprising a luminescent solar concentrator with multiple planar layers that are wavelength conversion layers, and the luminescent solar concentrator is mounted onto rigid base/solar cell assemblies to form a rigid structure, with a frame encapsulation to prevent moisture ingress.

FIG. 16 illustrates an embodiment of a packaged luminescent solar concentrator panel comprising a luminescent solar concentrator with a single planar layer that is a wavelength conversion layer, and the luminescent solar concentrator is mounted onto a rigid base/solar cell assembly to form a rigid structure, with a frame encapsulation to prevent moisture ingress.

FIG. 17 illustrates an embodiment of a packaged luminescent solar concentrator panel comprising a luminescent solar concentrator, wherein the luminescent solar concentrator comprises multiple glass or polymer layers and a single wavelength conversion layer, and the luminescent solar concentrator is mounted onto a rigid base/solar cell assembly to form a rigid structure, with a frame encapsulation to prevent moisture ingress.

FIG. 18 illustrates an embodiment of a packaged luminescent solar concentrator panel comprising a luminescent solar concentrator, wherein the luminescent solar concentrator comprises multiple glass or polymer layers and multiple wavelength conversion layers, and the luminescent solar concentrator is mounted onto a rigid base/solar cell assembly to form a rigid structure, with a frame encapsulation to prevent moisture ingress.

FIG. 19 illustrates an embodiment of a packaged luminescent solar concentrator panel comprising a luminescent solar concentrator, wherein the luminescent solar concentrator comprises multiple glass or polymer layers and multiple wavelength conversion layers, and the luminescent solar concentrator is mounted onto a rigid base/solar cell assembly to form a rigid structure, with a frame encapsulation to prevent moisture ingress.

FIG. 20 illustrates an embodiment of a packaged luminescent solar concentrator panel comprising a luminescent solar concentrator, wherein the luminescent solar concentrator comprises multiple glass or polymer layers and multiple wavelength conversion layers, and the luminescent solar concentrator is mounted onto a rigid base/solar cell assembly to form a rigid structure, with a frame encapsulation to prevent moisture ingress.

FIG. 21 illustrates an embodiment of a packaged luminescent solar concentrator panel comprising a luminescent solar concentrator, wherein the luminescent solar concentrator comprises multiple glass or polymer layers and multiple wavelength conversion layers, and the luminescent solar concentrator is mounted onto a rigid base/solar cell assembly to form a rigid structure, with a frame encapsulation to prevent moisture ingress.

FIG. 22 illustrates an embodiment of a packaged luminescent solar concentrator panel comprising a luminescent solar concentrator, wherein the luminescent solar concentrator comprises multiple glass or polymer layers and a wavelength conversion layer, and the rigid base/solar cell assembly are mounted onto the luminescent solar concentrator on the edge of the major planar surface to form a rigid structure, with the corner ground and polished at an angle of about 30 to about 60 degrees, and a mirror surface is applied to reflect the photons into the solar cell, with a frame encapsulation to prevent moisture ingress.

FIG. 23 illustrates an embodiment of a large area packaged luminescent solar concentrator panel comprising a luminescent solar concentrator, wherein the luminescent solar concentrator comprises multiple glass or polymer layers and a wavelength conversion layer, and at least one rigid base/solar cell assembly are mounted onto the luminescent solar concentrator on the back of the major planar surface to form a rigid structure, with a frame encapsulation to prevent moisture ingress.

FIG. 24 illustrates an embodiment of a large area packaged luminescent solar concentrator panel comprising a luminescent solar concentrator, wherein the luminescent solar concentrator comprises multiple glass or polymer layers and a wavelength conversion layer, and rigid base/solar cell assemblies are mounted onto the luminescent solar concentrator on both the back of the major planar surface and the edge surface to form a rigid structure, with frame encapsulation to prevent moisture ingress.

FIG. 25 illustrates an embodiment of a packaged luminescent solar concentrator panel comprising a luminescent solar concentrator, wherein the luminescent solar concentrator comprises a single planar layer of glass or polymer and one wavelength conversion layer, and a rigid base/solar cell assembly is mounted onto the luminescent solar concentrator on the edge surface to form a rigid structure, with a frame encapsulation to prevent moisture ingress.

### DETAILED DESCRIPTION OF THE CERTAIN EMBODIMENTS

Several different types of mature photovoltaic devices have been developed, including a Silicon based device, a III-V and II-VI PN junction device, a Copper-Indium-Gallium-Selenium (CIGS) thin film device, an organic sensitizer device, an organic thin film device, and a Cadmium Sulfide/Cadmium Telluride (CdS/CdTe) thin film device, to name a few. More detail on these devices can be found in the literature, such as Lin et al., “High Photoelectric Conversion Efficiency of Metal Phthalocyanine/Fullerene Heterojunction Photovoltaic Device” (International Journal of Molecular Sciences 2011). One of the problems with solar arrays is the difficulty and expense of making the semiconductor materials. In order for these devices to be competitive with traditional energy generating methods, their efficiency and cost require improvement.

One technique that has been investigated to improve efficiency and cost is with the use of light concentrating devices. However, only a finite amount of solar energy per square foot of the earth's surface is available for a given latitude and time of day and year. This amount can also be diminished by adverse weather conditions. Consequently, to generate the desired amount of electricity, it is necessary to utilize a large enough collection area, while taking into account the limited photoelectric conversion efficiency of the photovoltaic devices.

Some concentrators depend on the use of a lens to focus the sunlight on a photovoltaic cell, while others use mirrors for the same purpose. Either of these approaches allows sunlight from a large area to be collected and converted by one or more cells having a much smaller area. The exposed surface area ratios run from 5:1 to as much as 1000:1 in some cases. This approach is based upon the idea that it is cheaper to cover a surface with mirrors or lenses than with photovoltaic cells. However, such devices require a mechanism to point the apparatus accurately at the sun, which involves the use of moving parts, a sensing system or other form of control. Furthermore, on cloudy days, when the majority of the light is diffuse and cannot be readily focused, this type of concentrator can gather little solar energy.

Luminescent solar concentrators (“LSC”) can absorb solar light from a large insolated area and concentrate the emitted fluorescent light to a small area to which solar cells can be attached, were proposed for a light concentrating technique to lower cost and improve efficiency of solar cell devices. The luminescent solar concentrators function based on the entrance of solar radiation into a homogeneous medium containing a fluorescent species where the emission range of these species has minimum amount of overlap with the absorption range. The emitted photons are internally reflected and concentrated towards the edge of a collector. The concentrators can be formulated in any geometrical shape (e.g. a rectangle, square, parallelogram, etc.) and used as, usually, a thin plate. The concentration of light trapped in the plate is proportional to the ratio of the surface area to the edges. The advantages of luminescent solar concentrators over conventional solar concentrators include a high collection efficiency of both direct and diffuse light, good heat dissipation from the large area of the collector plate in contact with air, so that essentially “cold light” is used for converter devices such as silicon cells, whose efficiency is reduced by high temperatures. Also, with luminescent solar concentrators tracking of the sun is unnecessary, and choice of the luminescent species allows optimal spectral matching of the concentrated light to the maximum sensitivity of the photovoltaic (PV) process, minimizing undesirable side reactions in the solar cells.

These references describe luminescent solar concentrator devices of various structures, all of which claim the use of a luminescent compound to provide the photon absorption and re-emission. However, these references give little or no detail on types or specific compounds to use within the concentrators.

Luminescent solar collector for high efficiency conversion of solar energy to electrical energy which utilizes specific commercially available organic dyes, GF Orange-Red, Fluorol 555, oxazine-4-perchlorate, LDS 730, LDS 750, BASF 241, BASF 339, and combinations thereof with each other or with GF Clear or with 3-phenyl-fluoranthene. However, it is now well known that the photostability of these dyes is very poor. Therefore, these dyes are unusable in solar array devices which require life-times of 20+ years. While there has been much work developing a variety of new and different luminescent solar concentrator structures, there has been very little work incorporating these structures into a functional package or panel that can readily be applied to buildings or structures to generate electricity.

The present invention generally relates to a packaged luminescent solar concentrator panel comprising at least one photovoltaic or solar cell, a luminescent solar concentrator device, and a rigid base. In some embodiments, the luminescent solar concentrator comprises a planar layer and at least one wavelength conversion layer. In some embodiments, the luminescent solar concentrator comprises a wavelength conversion layer. In some embodiments the wavelength conversion layer comprises one or more chromophores. In some embodiments, the at least one solar cell is adhered to the rigid base using a thermally conductive adhesive. In some embodiments, a surface of the luminescent solar concentrator is mounted to the solar cell using an optically transparent adhesive. In some embodiments, the packaged luminescent solar concentrator panel may further comprise a frame encapsulating or engaging the solar cell and/or the base. In some embodiments, a low index adhesive is used to seal the gap between the frame and the luminescent solar concentrator and/or the base. In some embodiments, the wavelength conversion layer may comprise polymer, sol-gel or glass films doped with luminescent dyes. A packaged luminescent solar concentrator panel may contain multiple small luminescent solar concentrator devices which are mounted together using two sided frame. In some embodiments, the luminescent solar concentrator acts to absorb incident photons of a particular wavelength range, and re-emit those photons at a different wavelength, wherein the re-emitted photons are internally reflected and refracted until they reach the photovoltaic device or solar cell where they can be absorbed and converted into electricity. The packaged luminescent solar concentrator panel collects both direct and diffuse light and provides highly efficient and low cost solar harvesting solutions by using a minimal amount of expensive solar cells. The packaged luminescent solar concentrator panel is well suited for building integrated photovoltaics such as sunroofs, skylights, and facades of commercial and residential buildings.

A variety of packaged luminescent solar concentrators are described below to illustrate various examples that may be employed to achieve one or more desired improvements. These examples are only illustrative and not intended in any way to restrict the general inventions presented and the various aspects and features of these inventions. Furthermore, the phraseology and terminology used herein is for the purpose of description and should not be regarded as limiting. No features, structure, or step disclosed herein is essential or indispensable. In the present disclosure, where conditions and/or structures are not specified, the skilled artisan in the art can readily provide such conditions and/or structures, in view of the present disclosure, as a matter of routine experimentation.

In some embodiments, the packaged luminescent solar concentrator panel provides high efficiency low cost solar harvesting. Some embodiments of the present invention provide a packaged luminescent solar concentrator panel comprising at least one photovoltaic device (e.g., solar cell), a luminescent solar concentrator, and a rigid base (e.g. a strip of rigid material, support, etc.). In some embodiments, a rigid base is combined to a photovoltaic device and a solar concentrator to provide a packaged luminescent solar concentrator panel. In some embodiments, the at least one solar cell is mounted to the rigid base using a thermally conductive adhesive, and the surface of the luminescent solar concentrator is mounted to the at least one solar cell using a transparent adhesive. In some embodiments, a frame is used to encapsulate the at least one solar cell, and low refractive index adhesives are used to seal the gap between the luminescent solar concentrator device and the frame. In some embodiments the luminescent solar concentrator device comprises at least one planar layer and at least one wavelength conversion layer, wherein the at least one planar layer and the at least one wavelength conversion layer may or may not be the same layer. In some embodiments, the at least one planar layer has a major top surface for receipt of incident solar radiation, a bottom surface, and four edge surfaces. In some embodiments, the wavelength conversion layer comprises a glass, sol-gel, or polymer matrix film doped with a luminescent material, wherein the luminescent material acts to absorb incident photons of a particular wavelength range, and re-emit those photons at a different wavelength, wherein the re-emitted photons are internally reflected and refracted within the luminescent solar concentrator until they reach the portion of the surface where the solar cell is mounted, and they may then pass through the highly transparent adhesive and into the at least one solar cell for conversion into electricity. The packaged luminescent solar concentrator panel collects both direct and diffuse light and provides highly efficient and low cost solar harvesting solutions by using a minimal amount of expensive solar cells. The packaged luminescent solar concentrator panel is well suited for building integrated photovoltaics such as sunroofs, skylights, and facades of commercial and residential buildings.

The packaged luminescent solar concentrator panel may have a variety of structures. In some embodiments, the packaged luminescent solar concentrator panel comprises a single luminescent solar concentrator shaped as a flat sheet having a face portion and edge portions. In some embodiments, the luminescent solar concentrator has a rigid base wrapped around the perimeter edges to form a rigid structure. In some embodiments, the packaged luminescent solar concentrator panel further comprises a frame which is wrapped around the outside edges of the luminescent solar concentrator to cover and encapsulate the rigid base. In some embodiments, the packaged luminescent solar concentrator panel comprises multiple luminescent solar concentrator layers which are mounted into a single panel using multiple two sided frames. In some embodiments, the packaged luminescent solar concentrator panel comprises solar cells which are mounted to a portion of the back of the major planar surface, wherein the rigid base is mounted to the solar cells to form a rigid structure.

In some embodiments of the packaged luminescent solar concentrator panel, the adhesive layer (e.g. thermally conductive adhesive) may be a tape or a film. In some embodiments, the thermally conductive adhesive may be a tape or a film with a thermal conductivity at a minimum of about 1 W/mK. In some embodiments, the adhesive layer comprises a substance selected from the group consisting of rubber, acrylic, silicone, vinyl alkyl ether, polyester, polyamide, urethane, fluorine, epoxy, ethylene vinyl acetate, polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof. In some embodiments, the thermally conductive adhesive may be MASTER BOND EP21TCHT-1, a two component, thermally conductive epoxy from Master Bond Inc.

In some embodiments, the rigid base comprises a metal, metal composite (e.g. a metal and a non-metal species), metal alloy, ceramic, plastic material, or any combination thereof. In some embodiments, the rigid base comprises aluminum, tin, bronze, steel, iron, copper, or any combination thereof. In some embodiments, the rigid base provides enhanced mechanical and physical stability to the luminescent solar concentrator and/or photovoltaic device and/or the luminescent solar concentrator, photovoltaic device assembly. In some embodiments, the rigid base provides a structure that can easily be inserted into a frame or support. In some embodiments, the rigid base protects the luminescent solar concentrator and/or the photovoltaic device during transport, installation (e.g., insertion into a frame, etc.), and use.

In some embodiments, the frame comprises metal, metal composite (e.g. a metal and a non-metal species), metal alloy, polymer, plastic, wood, or any combination thereof. In some embodiments, the frame comprises aluminum, tin, bronze, steel, iron, copper, or any combination thereof. In some embodiments, the frame provides enhanced mechanical to the packaged luminescent solar concentrator. In some embodiments, the frame provides a structure that can easily be inserted into a window frame or frame support. In some embodiments, the frame protects the luminescent solar concentrator and/or the photovoltaic device during transport, installation, and use.

In some embodiments of the packaged luminescent solar concentrator panel, the transparent adhesive may be a tape or a film. Various types of adhesives may be used. In some embodiments, the transparent adhesive layer comprises a substance selected from the group consisting of rubber, acrylic, silicone, vinyl alkyl ether, polyester, polyamide, urethane, fluorine, epoxy, ethylene vinyl acetate, polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof. The transparent adhesive can be permanent or non-permanent. In some embodiments, the thickness of the transparent adhesive layer is in the range from about 1 μm and about 100 μm, about 1 μm to about 10 μm, about 10 μm to about 20 μm, about 20 μm to about 30 μm, about 30 μm to about 50 μm, about 50 μm to about 75 μm, about 75 μm to about 100 μm, or over 100 μM In some embodiments, the refractive index of the adhesive layer is in the range of about 1.40 to about 1.70. In some embodiments, the transparent adhesive comprises a UV epoxy, such as Norland optical adhesive 68T from Norland Products Inc. In some embodiments, the transparent adhesive layer is transparent such that transmission of light in the visible wavelength range is greater than 60%, greater than 70%, greater than 80%, greater than 90%, or greater than 95%.

In some embodiments of the packaged luminescent solar concentrator panel, a frame is used to encapsulate the solar cell. An adhesive is used to seal the gap between the luminescent solar concentrator and the frame. Various types of adhesives may be used. In some embodiments, the adhesive layer comprises a substance selected from the group consisting of rubber, acrylic, silicone, vinyl alkyl ether, polyester, polyamide, urethane, fluorine, epoxy, ethylene vinyl acetate, polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof. In some embodiments, low refractive index adhesives are used to seal the gap between the luminescent solar concentrator and the frame in order to reduce optical loss. In some embodiments of the packaged luminescent solar concentrator panel, the low refractive index adhesive comprises a fluorinated polymer material. In some embodiments, the low refractive index adhesive may be MASTER BOND EP21TCHT-1, a two component, thermally conductive epoxy from Master Bond Inc.

Several embodiments of the luminescent solar concentrator device and packaged luminescent solar concentrator devices are disclosed below. Each luminescent solar concentrator device can have any one or more of the below features or combinations of features. Therefore, it should be appreciated that, while the below disclosure at times discusses single exemplary luminescent solar concentrator devices, in some embodiments any one of the luminescent solar concentrator devices below may have one or more features of the examplary devices.

FIG. 1 shows a rigid base 102 comprising a rigid material (e.g., a metal, plastic material, composite material, carbon fiber material, or the like). In some embodiments, the rigid material is a metal such as aluminum, iron, gold, silver, bronze, copper, etc. In some embodiments, the rigid material 102 can be adhered to a photovoltaic device 103 (e.g. a solar cell, etc.) by an adhesive layer 101 (e.g. a tape, a thermally conductive tape, a glue, or the like).

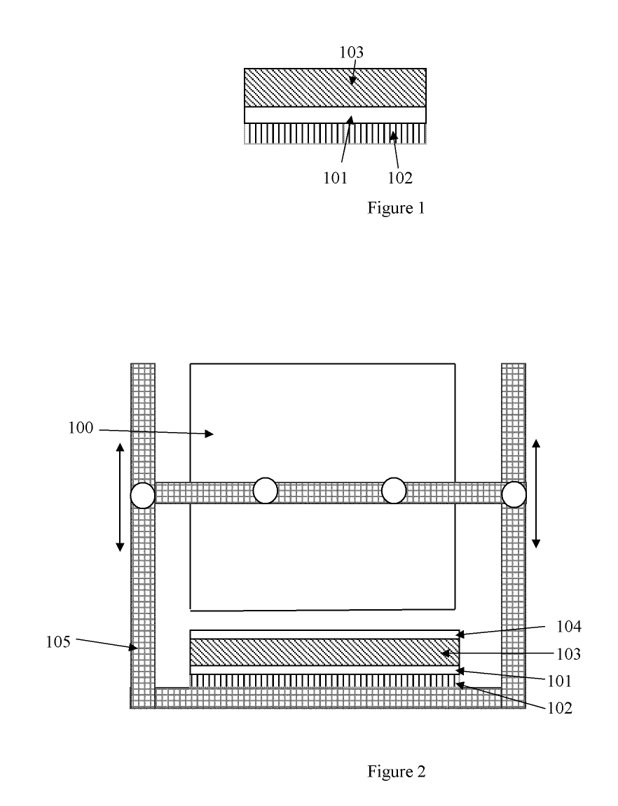

FIG. 2 shows one embodiment of the functionalization of a luminescent solar concentrator device 100 to a photovoltaic device 103 and a rigid base 102 to form a packaged functional panel. FIG. 2 shows a view of the top surface of the luminescent solar concentrator as it is brought into proximity to the photovoltaic device 103 and the rigid base 102. The luminescent solar concentrator can have one or more sides (e.g., edge surfaces). In some embodiments, the luminescent concentrator has one side (e.g., it can be circular), two, three, four, five, six, seven, or more sides. The luminescent concentrator of FIG. 2 is shown having four sides. In some embodiments, the luminescent concentrator also has a bottom surface that is spaced apart from the top surface and wherein the edge has an edge surface that extends from the top surface to the bottom surface. In some embodiments, as discussed below the top surface is configured to receive photons from a photon source. In some embodiments, the top surface is in a position that is closer to the photon source than is the bottom surface.

Steps used to form the device in FIG. 2 are as follows. First, an adhesive layer 101 (e.g. a thermally or light conductive adhesives, thermally or light conductive tapes, [such as MASTER BOND EP21TCHT-1 which is a two component, thermally conductive epoxy from Master Bond Inc.], etc.) is placed on the rigid base 102. Next, a solar cell 103 is placed on the adhesive layer 101 sandwiching the adhesive layer 101 between the solar cell 103 and the rigid base 102. In some embodiments, one or more of the rigid base, the solar cell, the adhesive layers, and the edge surface of the luminescent solar concentrator are flush when assembled. In some embodiments, having a flush assembly allows the assembly to be placed into a securing member (e.g., a frame, etc.) for easy installation and/or transport.

In some embodiments, the rigid base, the solar cell, the adhesive layers and the edge surface of the luminescent solar concentrator are not flush and can be of different configurations to form lips and edges. These lips and/or edges can be used to snap the assembly into place in, for instance, a frame with matching features (similar to a lock and key).

If desired, the solar cell panel 103 can then be gently pressed down on the thermally conducting tape 101 and rigid base 102 to remove air bubbles. In some embodiments, the thermally conducting tape 101 is then allowed to cure (e.g. at, above, or below room temperature) for a period of time (e.g. in the range from about 0-1 hour, 1-4 hours, 4-8 hours, 8-12 hours, 12-24 hours, or longer).

Next, an transparent adhesive 104 (e.g., a UV Epoxy Norland optical adhesive 68T from Norland Products Inc., etc.) is placed on the solar cell 103 at a position located away from the rigid base. Then, the luminescent solar concentrator 100 is placed over the base 102 and solar cell panel 103 assembly and affixed by the transparent adhesive 104. FIG. 2 shows the luminescent solar concentrator 100 just before it contacts the transparent adhesive 104. In some embodiments, the solar concentrator 100 is placed such that its edge is aligned with an edge of the solar cell panel 103.

In some embodiments, the rigid base 102 is selected to have outer dimensions which match the dimensions of the edge of the luminescent solar concentrator device. In some embodiments, the solar cell panel 103 is selected to have dimensions matching the rigid base 102 and the luminescent solar concentrator.

In some embodiments, as shown in FIG. 2, the placement of the luminescent solar concentrator 100 is accomplished using a mounting rack 105 (e.g., a frame configured to guide the luminescent solar concentrator into place). The mounting rack 105 can be composed of any suitable material (metal, plastic, composite, etc.). The mounting rack 105 can further comprise positioning elements (e.g., balls, wheels, pads, etc.) that allow the luminescent solar concentrator to smoothly move into position and in contact with the transparent adhesive 104.

If desired, the luminescent concentrator 100 can be gently pressed down onto the transparent adhesive 104 on a face of the solar cell 103 to remove all air bubbles. In some embodiments, a pre-curing step can then be performed to partially cure the transparent adhesive 104 (e.g., using a pre-curing agent, for example. an ELC-405 light curing system from Electro-Lite Corporation, etc.). In some embodiments, a curing step can be performed instead of or in addition to the pre-curing step to seal the transparent adhesive 104. In some embodiments, a curing agent (e.g. Loctite®, Zeta® 7411 UV Flood Curing System, etc.) is used to facilitate curing.

In some embodiments, the pre-curing step above is accomplished using a pre-curing time of at least about 1 second, 5 seconds, 10 seconds, 30 seconds, 60 seconds, 90 seconds, 2 minutes, 5 minutes, 10 minutes, times and ranges between the aforementioned values, and otherwise. In some embodiments, pre-curing is accomplished in two steps, curing the transparent adhesive 104 first to the solar cell panel 103, then to the luminescent solar concentrator 100. In some embodiments, the curing step above is accomplished using a curing time of at least about 1 second, 5 seconds, 30 seconds, 60 seconds, 2 minutes, 3 minutes, 5 minutes, 10 minutes, 20 minutes, times and ranges between the aforementioned values, and otherwise. In some embodiments, curing is accomplished in two steps, curing the transparent adhesive 104 first to the solar cell panel 103, then to the luminescent solar concentrator 100. In some embodiments, one or more of the pre-curing or curing steps are not performed. In some embodiments, a final curing step is performed after the entire packaged device is assembled.

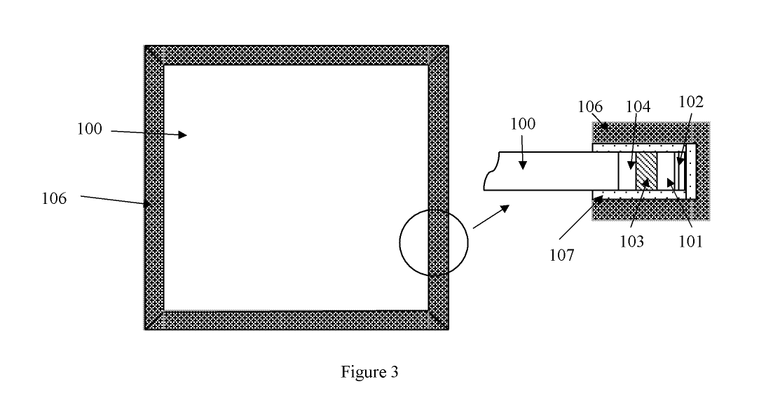

In some embodiments, the above steps can be repeated for each of the other three sides of the luminescent solar concentrator 100 shown in FIG. 2. In some embodiments, all sides of the luminescent solar concentrator 100 can be mounted to rigid base/solar cell assemblies. In some embodiments, once the mounting of the rigid base/solar cell assembly to the luminescent solar concentrator is accomplished, support structures (e.g. frames) composed of a rigid material (e.g., metal, plastic, composite, etc.) can be used to encapsulate the sides of the rigid base/solar cell/luminescent solar concentrator assembly. For example, FIG. 3 shows the use of four U-shaped frames 106 made of a rigid material (e.g. aluminum) used to cover the rigid base 102/solar cell panel 103/luminescent solar concentrator 100 assembly on the four sides. In some embodiments, an adhesive (e.g., glue, epoxy, tape, etc.) is used to bond the rigid base 102/solar cell panel 103/luminescent solar concentrator 100 assembly to the frame 106. In some embodiments, a low refractive index adhesive 107 (e.g., MASTER BOND EP21TCHT-1, etc.) can be used between the frame sides 106 and the edge of the rigid base 102/solar cell panel 103/luminescent solar concentrator 100 assembly to seal the rigid base 102/solar cell panel 103/luminescent solar concentrator 100 assembly (or solar panel) in the frame. In some embodiments, this assembly also provides good heat conductivity. In some embodiments, a solar panel and frame together comprise a packaged luminescent solar concentrator.

In some embodiments, electricity generated by the solar cells 103 can be transported using a wiring system which is connected to these devices. In some embodiments, the packaged luminescent solar concentrator panel further comprises at least one conduit (e.g. a wire, conductive polymer, carbon fiber, etc.) which connects the solar cells 103 and enables transport of the generated electricity.

In some embodiments, the packaged luminescent solar concentrator panel comprising a luminescent solar concentrator, and at least one solar cell or photovoltaic device is amenable for use with all different types of solar cell devices. Devices, such as a Silicon based device, a III-V or II-VI PN junction device, a Copper-Indium-Gallium-Selenium (CIGS) thin film device, an organic sensitizer device, an organic thin film device, or a Cadmium Sulfide/Cadmium Telluride (CdS/CdTe) thin film device, can be improved. In some embodiments, the panel comprises at least one photovoltaic device or solar cell comprising a Cadmium Sulfide/Cadmium Telluride solar cell. In some embodiments, the photovoltaic device or solar cell comprises a Copper Indium Gallium Diselenide solar cell. In some embodiments, the photovoltaic or solar cell comprises a III-V or II-VI PN junction device. In some embodiments, the photovoltaic or solar cell comprises an organic sensitizer device. In some embodiments, the photovoltaic or solar cell comprises an organic thin film device. In some embodiments, the photovoltaic device or solar cell comprises an amorphous Silicon (a-Si) solar cell. In some embodiments, the photovoltaic device or solar cell comprises a microcrystalline Silicon (μc-Si) solar cell. In some embodiments, the photovoltaic device or solar cell comprises a crystalline Silicon (c-Si) solar cell.

The shape of the luminescent solar concentrator device helps to concentrate the solar energy towards the edges because the incoming photon, which may be incident on the device in a variety of angles, once absorbed by the chromophore compound in the wavelength conversion layer, can be re-emitted in a direction that will internally reflect within the device rather than in a direction that will cause it to exit the device. This is due to the thin planar geometry of the luminescent solar concentrator device. However, photons do not necessarily need to be absorbed and re-emitted by the chromophore compound in order to be internally reflected and refracted with the luminescent solar concentrator device. In some embodiments, the incident photons into the luminescent solar concentrator may be internally reflected and refracted within the device without necessarily being absorbed by the chromophore and re-emitted.

In some embodiments, as discussed above, the luminescent solar concentrator comprises a wavelength conversion layer. In some embodiments, the luminescent solar concentrator comprises one, two, three, four, five, or more wavelength conversion layers. In some embodiments, the wavelength conversion layer(s) form the top and/or bottom surface of the luminescent solar concentrator. In some embodiments, the wavelength conversion layer(s) form the edge surface of the luminescent solar concentrator.

In some embodiments, the wavelength conversion layer or layers of the luminescent solar concentrator may be sandwiched in between glass or polymer plates. In some embodiments, the wavelength conversion layer or layers form the top and/or bottom surface of the luminescent solar concentrator. In some embodiments, the glass or polymer plates also act to internally reflect and refract photons towards the edge surface.

In some embodiments, the luminescent solar concentrator comprises two or more wavelength conversion layers. In some embodiments, the wavelength conversion layers can comprise the same or different chromophores. In some embodiments, each wavelength conversion layer can comprise one, two, three, four, five, six, seven, eight, or more chromophores. In some embodiments, each of the wavelength conversion layer independently comprises a different chromophore such that each of the wavelength conversion layers absorbs photons at a different wavelength range.

In some embodiments, where multiple wavelength conversion layers are stacked from top to bottom of the luminescent solar concentrator, the bottom layer wavelength conversion layer uses one or more chromophore compounds that are excited by different wavelengths than wavelength conversion layers closer to the top of the luminescent solar concentrator.

In some embodiments, the top wavelength conversion layer of the luminescent solar concentrator may be transparent to the wavelengths of light that the bottom wavelength conversion layer of the luminescent solar concentrator will absorb. In some embodiments, a top wavelength conversion layer comprises a chromophore which is designed to absorb harmful UV radiation and convert it to lower energy photons. In some embodiments, a middle wavelength conversion layers are designed to absorb visible light, and are positioned in descending order with the layers absorbing the short wavelengths on top, and longer wavelengths towards the bottom. In some embodiments, a bottom wavelength conversion layer is designed to absorb near IR wavelengths.

One advantage of positioning the wavelength conversion layers in descending order, with short wavelength absorption at the top, and long wavelength absorption at the bottom, is that the harmful UV radiation is mostly absorbed at the top of the device and does not reach the successive layers. The majority of chromophore photodegradation is due to exposure to UV radiation, so eliminating this exposure in the successive layers greatly increases the photostability of the chromophore compounds in these layers, which translates to a much longer device lifetime.

In some embodiments, the wavelength conversion layer comprises a polymer matrix and at least one organic photostable chromophore. In some embodiments of the luminescent solar concentrator, the polymer matrix of the wavelength conversion layer is formed from a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof.

In some embodiments of the luminescent solar concentrator, the polymer matrix of the wavelength conversion layer may be made of one host polymer, a host polymer and a co-polymer, or multiple polymers.

In some embodiments, the polymer matrix material used in the wavelength conversion layer has a refractive index in the range of about 1.40 to about 1.70. In some embodiments, the refractive index of the polymer matrix material used in the wavelength conversion layer is in the range of about 1.45 to about 1.55, from about 1.40 to about 1.50, from about 1.50 to about 1.60, or from about 1.60 to about 1.70.

The overall thickness of the at least one wavelength conversion layer may also vary over a wide range. In some embodiments, the wavelength conversion layer thickness is in the range of about 0.1 μm to about 1 mm. In some embodiments, the wavelength conversion layer thickness is in the range of about 0.5 μm to about 0.5 mm. In some embodiments, the wavelength conversion layer thickness is in the range of about 0.1 μm to about 0.5 μm, about 0.5 μm to about 1.0 μm, about 1.0 μm to about 100 μm, about 100 μm to about 0.5 mm, or about 0.5 mm to about 1.0 mm, ranges in between the aforementioned ranges, and otherwise.

In some embodiments, the chromophore compounds utilized in the luminescent solar concentrator exhibit minimal absorption band and emission band overlap, which alleviates the possibility of re-adsorption within the device.

In some embodiments, the at least one chromophore is independently present in the polymer matrix of the wavelength conversion layer in an amount in the range of about 0.01 wt % to about 10.0 wt %, about 0.01 wt % to about 3.0 wt %, about 0.05 wt % to about 2.0 wt %, or about 0.1 wt % to about 1.0 wt %, by weight of the polymer matrix.

In some embodiments, it may be desirable to have multiple chromophores in the wavelength conversion layer, depending on the solar cell that is to be used in the module. For example, in a photovoltaic module system having an optimum photoelectric conversion at about 500 nm wavelength, the efficiency of such a system can be improved by converting photons of other wavelengths into 500 nm wavelengths, while the stability may also be improved by using a chromophore which absorbs the harmful UV photons and reduces the exposure of the other chromophores to the UV radiation. In such instance, a first chromophore may act to convert photons having wavelengths less than 410 nm into photons of a wavelength of about 430 nm, while a second chromophore may act to convert photons having wavelengths in the range of about 420 nm to about 450 nm into photons of a wavelength of about 470 nm. In some embodiments, a third chromophore may act to convert photons having wavelengths in the range of about 450 nm to about 480 nm into photons of a wavelength of about 500 nm. Particular wavelength control may be selected based upon the chromophore(s) utilized.

In some embodiments, additional chromophores may be located in separate wavelength conversion layers or sublayers within the luminescent solar concentrator. For example, a first wavelength conversion layer comprises a chromophore which acts to convert photons having wavelengths in the range of about 420 to 450 nm into photons of a wavelength of about 500 nm, and a second wavelength conversion layer comprises a chromophore which acts to convert photons having wavelengths in the range of about 450 to 480 nm into photons of a wavelength of about 500 nm. In some embodiments, the wavelength conversion layers are separated by an air gap, such that the photons once absorbed, are internally reflected and refracted only within the wavelength conversion layer in which they were absorbed. In some embodiments, each wavelength conversion layer is optically attached to at least one glass or polymer plate, such that once the photons are absorbed and re-emitted, they are internally reflected and refracted within the coupled wavelength conversion layer and glass or polymer plate.

In some embodiments, the wavelength conversion layer of the luminescent solar concentrator comprises at least one planar layer and at least one wavelength conversion layer, wherein the wavelength conversion layer comprises at least one chromophore and an optically transparent polymer matrix. In some embodiments, this wavelength conversion layer is formed by first synthesizing the chromophore/polymer solution in the form of a liquid or gel, applying the chromophore/polymer solution to a glass or polymer plate using standard methods of application, such as spin coating or drop casting, then curing the chromophore/polymer solution to a solid form (i.e. heat treating, UV exposure, etc.) as is determined by the formulation design. Once dry, the film can then be used in the luminescent solar concentrator in a variety of structures.

As discussed above, FIG. 3 illustrates an embodiment of a packaged luminescent solar concentrator panel comprising a single luminescent solar concentrator 100. In some embodiments, the frame 106 encapsulates the outside edges of the panel, as shown. In some embodiments, the solar cells 103 are mounted to a rigid base 102 inside the frame 106 using a thermally conductive adhesive 101. In some embodiments, the luminescent solar concentrator 100 is mounted to the light incident side of the solar cell 103 using a transparent adhesive 104. In some embodiments, a low refractive index adhesive 107 is used to seal the gap between the luminescent solar concentrator 100 and the frame 106.

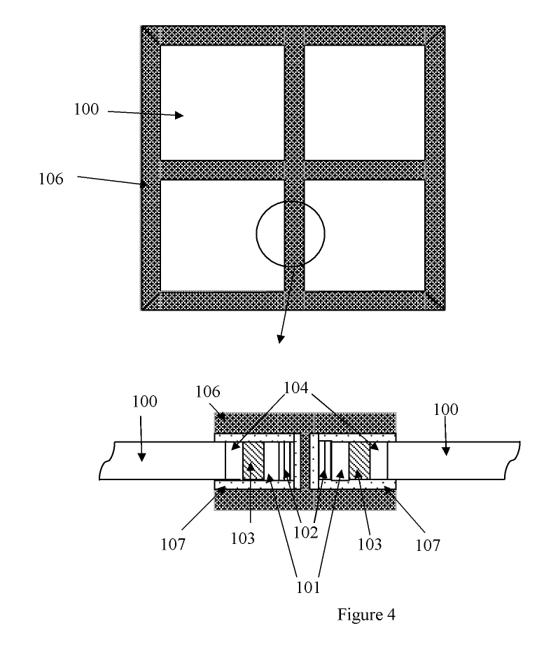

FIG. 4 illustrates an embodiment of a packaged luminescent solar concentrator panel comprising multiple (e.g. four) luminescent solar concentrators 100, wherein multiple two sided frames 106 (shown embedded in FIG. 4) and single sided frames 106 (as depicted in FIG. 3) are wrapped around the edges and edge surfaces of the luminescent solar concentrators 100. In some embodiments, as shown, the solar cells 103 are mounted on a rigid base 102 inside the frame 106 using a thermally conductive adhesive 101. In some embodiments, the luminescent solar concentrator is mounted to the light incident side of the solar cell using a transparent adhesive 104. In some embodiments, as shown, a low refractive index adhesive 107 is used to seal the gap between the luminescent solar concentrators and the frames.

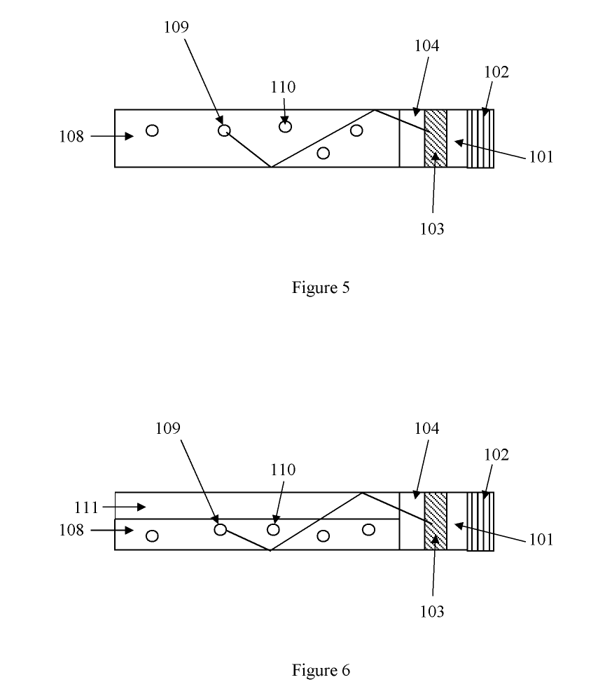

FIG. 5 a bisected view of an embodiment of a luminescent solar concentrator panel comprising a luminescent solar concentrator 100, a rigid base 102, and solar cells 103 to form a rigid structure. In some embodiments, as shown, the solar cells 103 are mounted to the rigid base 102 using a thermally conductive adhesive 101. In some embodiments, as shown, the edge of the luminescent solar concentrator 100 is mounted to the light incident side of the solar cell 103 using a transparent adhesive 104. In some embodiments, as shown, the luminescent solar concentrator 100 comprises a single planar layer 108 that is a wavelength conversion layer. In some embodiments, as illustrated, an incident photon 109 of a first wavelength enters the wavelength conversion layer. In some embodiments, the photon is absorbed by the at least one chromophore compound 110 and re-emitted at a second wavelength which is different than the first. In some embodiments, the re-emitted photon can then be internally reflected and refracted until it reaches the edge of the luminescent solar concentrator 100 where a solar cell 103 is mounted. In some embodiments, the re-emitted photon is absorbed by a photoelectric conversion layer of the solar cell, and converted into electricity. In some embodiments, photons that have not been absorbed and re-emitted by embedded chromophores may also reach the solar cell 103 via internal reflection and refraction within the luminescent solar concentrator 100.

FIG. 6 illustrates a bisected view of an embodiment of a luminescent solar concentrator panel comprising a luminescent solar concentrator 100, a rigid base 102, and a solar cell 103 to form a rigid structure. In some embodiments, as shown, the solar cells 103 are mounted to the rigid base 102 using a thermally conductive adhesive 101. In some embodiments, as shown, the edge of the luminescent solar concentrator 100 is mounted to the light incident side of the solar cell using a transparent adhesive 104. In some embodiments, as shown, the luminescent solar concentrator 100 may comprise a glass or polymer layer 111 on top of a wavelength conversion layer 108. In some embodiments, an incident photon 109 of a first wavelength enters the wavelength conversion layer, and is absorbed by the at least one chromophore compound 110 and re-emitted at a second wavelength which is different than the first. In some embodiments, the re-emitted photon is then internally reflected and refracted until it reaches the edges where a solar cell 103 is mounted. In some embodiments, the re-emitted photon is absorbed by the photoelectric conversion layer of the solar cell 103, and converted into electricity.

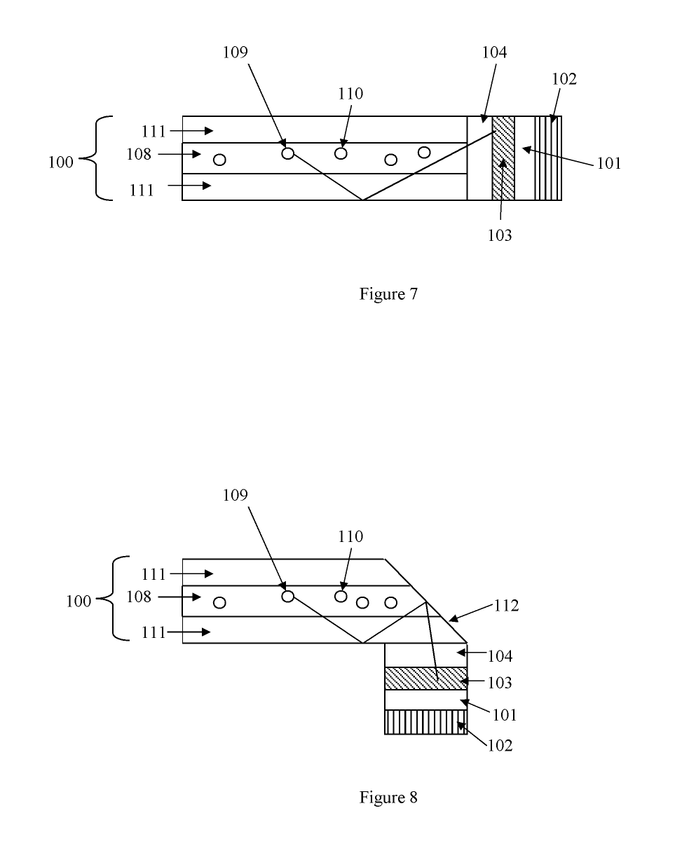

FIG. 7 illustrates a bisected view of an embodiment of a luminescent solar concentrator panel comprising a luminescent solar concentrator 100, a rigid base 102, and solar cells 103 to form a rigid structure. In some embodiments, as shown, the solar cells 103 are mounted to the rigid base using a thermally conductive adhesive 101. In some embodiments, as shown, the edge of the luminescent solar concentrator 100 is mounted to the light incident side of the solar cell 103 using a transparent adhesive 104. In some embodiments, as shown, the luminescent solar concentrator 100 comprises multiple glass or polymer layers 111 (forming the top and bottom of surface of the luminescent solar concentrator) and a wavelength conversion layer 108. In some embodiments, an incident photon 109 of a first wavelength enters the wavelength conversion layer, and is absorbed by the at least one chromophore compound 110 and re-emitted at a second wavelength which is different than the first, and is then internally reflected and refracted until it reaches the edge surface where a solar cell 103 is mounted. In some embodiments, the re-emitted photon is absorbed by the photoelectric conversion layer of the solar cell, and converted into electricity.

FIG. 8 illustrates a bisected view of an embodiment of a luminescent solar concentrator panel comprising a luminescent solar concentrator 100, a rigid base 102, and solar cells 103 to form a rigid structure. In some embodiments, as shown, the solar cells are mounted to the rigid base using a thermally conductive adhesive 101. In some embodiments, as shown, the rigid base/solar cell assembly are mounted onto the luminescent solar concentrator using a highly transparent adhesive 104 on the edge of the major planar surface. In some embodiments, as shown, the luminescent solar concentrator panel comprises a corner. In some embodiments, the corner is ground and polished at an angle of about 30 to about 60 degrees (or about 10 to about 30 degrees, about 30 to about 60 degrees or about 60 to about 80 degrees). In some embodiments, as shown, a mirror surface 112 is applied to reflect the photons into the solar cell. In some embodiments, the luminescent solar concentrator comprises multiple glass or polymer layers 111 and a wavelength conversion layer 108. In some embodiments, an incident photon 109 of a first wavelength enters the wavelength conversion layer 108 and is absorbed by the at least one chromophore compound 110. In some embodiments, the absorbed photon is re-emitted from the chromophore at a second wavelength which is different than the first. In some embodiments, the photon is then internally reflected and refracted until it reaches the surface where a solar cell 103 is mounted. In some embodiments, the photon is absorbed by the photoelectric conversion layer of the solar cell and converted into electricity.

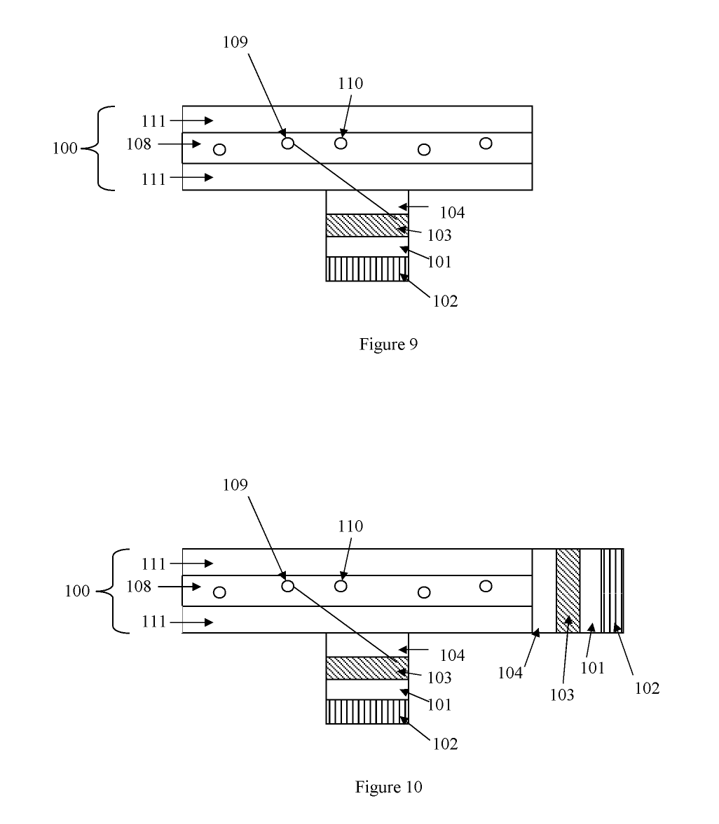

FIG. 9 illustrates a bisected view of an embodiment of a luminescent solar concentrator panel comprising a luminescent solar concentrator 100, a rigid base 102, and solar cells 103 to form a rigid structure. In some embodiments, as shown, the solar cells are mounted to the rigid base using a thermally conductive adhesive 101. In some embodiments, as shown, the rigid base/solar cell assembly are mounted onto the luminescent solar concentrator using a highly transparent adhesive 104 on the back of the major planar surface. In some embodiments, as shown, the luminescent solar concentrator comprises multiple glass or polymer layers 111 and a wavelength conversion layer 108. In some embodiments, an incident photon 109 of a first wavelength enters the wavelength conversion layer, and is absorbed by the at least one chromophore compound 110 and re-emitted at a second wavelength which is different than the first. In some embodiments, the photons are internally reflected and refracted until they reach the surface where a solar cell 103 is mounted. In some embodiments, the photons are absorbed by the photoelectric conversion layer of the solar cell, and converted into electricity.

FIG. 10 illustrates a bisected view of an embodiment of a large area luminescent solar concentrator panel comprising a luminescent solar concentrator 100, a rigid base 102, and solar cells 103 to form a rigid structure. In some embodiments, as shown, the solar cells 103 are mounted to the rigid base 102 using a thermally conductive adhesive 101. In some embodiments, as shown, the rigid base/solar cell assembly is mounted onto the luminescent solar concentrator 100 using a transparent adhesive 104 on both the back of the major planar surface and the edge surface. In some embodiments, the luminescent solar concentrator 100 comprises one or more glass or polymer layers 111 and a wavelength conversion layer 108. In some embodiments, an incident photon 109 of a first wavelength enters the wavelength conversion layer 108, and is absorbed by the at least one chromophore compound 110 and re-emitted at a second wavelength which is different than the first, and is then internally reflected and refracted until it reaches the surface where a solar cell 103 is mounted, and is absorbed by the photoelectric conversion layer of the solar cell, and converted into electricity.

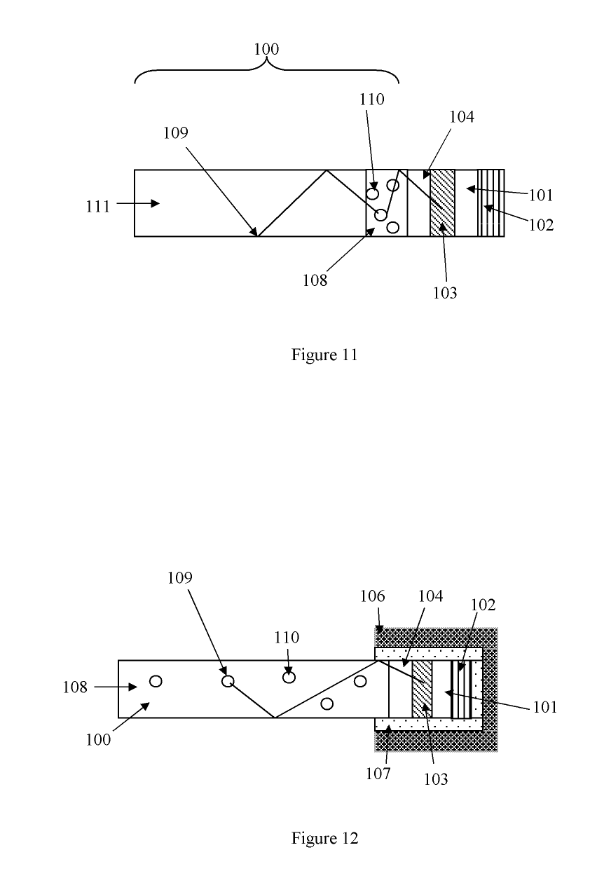

FIG. 11 illustrates a bisected view of an embodiment of a luminescent solar concentrator panel comprising a luminescent solar concentrator 100, a rigid base 102, and solar cells 103 to form a rigid structure. In some embodiments, as shown, the solar cells are mounted to the rigid base 102 using a thermally conductive adhesive 101. In some embodiments, as shown, the rigid base/solar cell assembly is mounted onto the edge surface of the luminescent solar concentrator 100 using a transparent adhesive 104. In some embodiments, the luminescent solar concentrator 100 comprises a glass or polymer layer 111 extending from the top surface of the luminescent solar concentrator to the bottom surface of the luminescent solar concentrator. In some embodiments, a wavelength conversion layer 108 (adjacent to the glass or polymer layers 111) also extends from the top surface of the luminescent solar concentrator to the bottom surface of the luminescent solar concentrator. In some embodiments, an incident photon 109 of a first wavelength enters the luminescent solar concentrator 100, and is absorbed by the at least one chromophore compound 110 and re-emitted at a second wavelength which is different than the first. In some embodiments, photons are internally reflected and refracted until they reaches the edges where a solar cell 103 is mounted. In some embodiments, the photons are then absorbed by the photoelectric conversion layer of the solar cell, and converted into electricity.

FIG. 12 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells 103 are mounted to the rigid base using a thermally conductive adhesive 101. In some embodiments, as shown, the edge of the luminescent solar concentrator is mounted to the light incident side of the solar cell using a highly transparent adhesive 104. In some embodiments, as shown, a frame 106 is used to encapsulate and prevent moisture ingress to the rigid base/solar cell/LSC assembly. In some embodiments, as shown, a low refractive index adhesive 107 is used to seal the gaps between the frame and the rigid base/solar cell/LSC assembly. In some embodiments, as shown, the luminescent solar concentrator 100 comprises a single planar layer that is a wavelength conversion layer 108. In some embodiments, an incident photon 109 of a first wavelength enters the wavelength conversion layer, and is absorbed by the at least one chromophore compound 110 and re-emitted at a second wavelength which is different than the first. In some embodiments, photons are internally reflected and refracted until they reach the edges where a solar cell 103 is mounted. In some embodiments, the photons are absorbed by the photoelectric conversion layer of the solar cell, and converted into electricity.

FIG. 13 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells are mounted to the rigid base using a thermally conductive adhesive 101. In some embodiments, as shown, the edge of the luminescent solar concentrator is mounted to the light incident side of the solar cell 103 using a highly transparent adhesive 104, with a frame 106 encapsulation to prevent moisture ingress. In some embodiments, as shown, a low refractive index adhesive 107 is used to seal the gaps between the frame and the rigid base/solar cell/LSC assembly. In some embodiments, the luminescent solar concentrator comprises multiple planar layers that are wavelength conversion layers 108. In some embodiments, an incident photon 109 of a first wavelength enters the wavelength conversion layer, and is absorbed by the at least one chromophore compound 110 and re-emitted at a second wavelength which is different than the first. In some embodiments, photons is then internally reflected and refracted until it reaches the edges where a solar cell 103 is mounted. In some embodiments, photons are absorbed by the photoelectric conversion layer of the solar cell and converted into electricity. In some embodiments, the wavelength conversion layers 108 are vertically spaced apart by a gap (e.g. by air, vacuum, gas, liquid, adhesive, etc.).

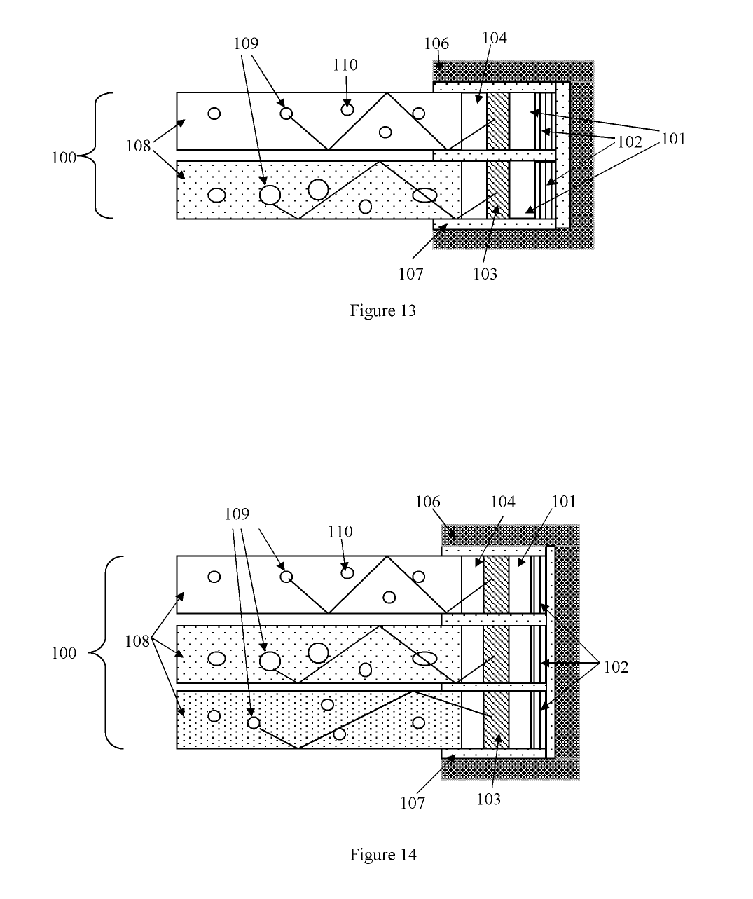

FIG. 14 illustrates an embodiment of a packaged luminescent solar concentrator panel comprising a luminescent solar concentrator 100, a rigid base 102, and solar cells 103 to form a rigid structure. In some embodiments, as shown, the solar cells are mounted to the rigid base using a thermally conductive adhesive 101. In some embodiments, as shown, the edge surface of the luminescent solar concentrator is mounted to the light incident side of the solar cell using a highly transparent adhesive 104. In some embodiments, as shown, a frame 106 is used to prevent moisture ingress to the the rigid base/solar cell/LSC assembly. In some embodiments, a low refractive index adhesive 107 is used to seal the gaps between the frame and the rigid base/solar cell/LSC assembly. In some embodiments, as shown, the luminescent solar concentrator 100 comprises multiple planar layers that are wavelength conversion layers 108. In some embodiments, as shown, an incident photon 109 of a first wavelength enters the wavelength conversion layer 108, and is absorbed by the at least one chromophore compound 110 and re-emitted at a second wavelength which is different than the first. In some embodiments, photons are internally reflected and refracted until they reach the edges where a solar cell 103 is mounted. In some embodiments, photons are absorbed by the photoelectric conversion layer of the solar cell and are converted into electricity. In some embodiments, the wavelength conversion layers 108 are vertically spaced apart by a gap (e.g. by air, vacuum, gas, liquid, adhesive, etc.).

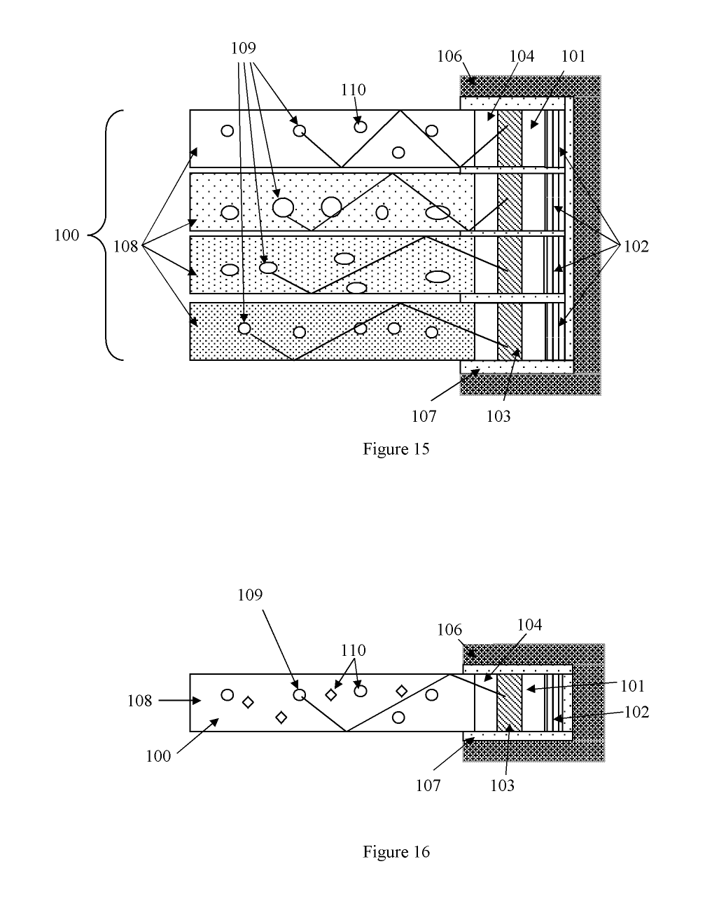

FIG. 15 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells are mounted to the rigid base using a thermally conductive adhesive 101. In some embodiments, as shown, the edge of the luminescent solar concentrator is mounted to the light incident side of the solar cell using a highly transparent adhesive 104, with a frame 106 encapsulation to prevent moisture ingress, and a low refractive index adhesive 107 is used to seal the gaps between the frame and the rigid base/solar cell/LSC assembly. In some embodiments, as shown, the luminescent solar concentrator 100 comprises multiple planar layers that are wavelength conversion layers 108. In some embodiments, an incident photon 109 of a first wavelength enters the wavelength conversion layer 108, and is absorbed by the at least one chromophore compound 110 and re-emitted at a second wavelength which is different than the first, and is then internally reflected and refracted until it reaches the edges where a solar cell 103 is mounted, and is absorbed by the photoelectric conversion layer of the solar cell, and converted into electricity. In some embodiments, the wavelength conversion layers 108 are vertically spaced apart (e.g. by air, vacuum, gas, liquid, adhesive, etc.).

FIG. 16 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells 103 are mounted to the rigid base 102 using a thermally conductive adhesive 101. In some embodiments, as shown, the edge of the luminescent solar concentrator 100 is mounted to the light incident side of the solar cell using a transparent adhesive 104, with a frame 106 encapsulation to prevent moisture ingress. In some embodiments, as shown, a low refractive index adhesive 107 is used to seal the gaps between the frame and the rigid base/solar cell/LSC assembly. In some embodiments, as shown, the luminescent solar concentrator 100 comprises a single planar layer comprising a wavelength conversion layer 108. In some embodiments, as shown, the wavelength conversion layer 108 comprises multiple (e.g., two, three, four, five, six, or more) different chromophores 110. In some embodiments, an incident photon 109 of a first wavelength enters the wavelength conversion layer and is absorbed by the two or more chromophore compounds 110. In some embodiments, the absorbed chromophore is re-emitted at a second wavelength which is different than the first. In some embodiments, the re-emitted chromophore is then internally reflected and refracted until it reaches the edges where a solar cell 103 is mounted, and is absorbed by the photoelectric conversion layer of the solar cell, and converted into electricity.

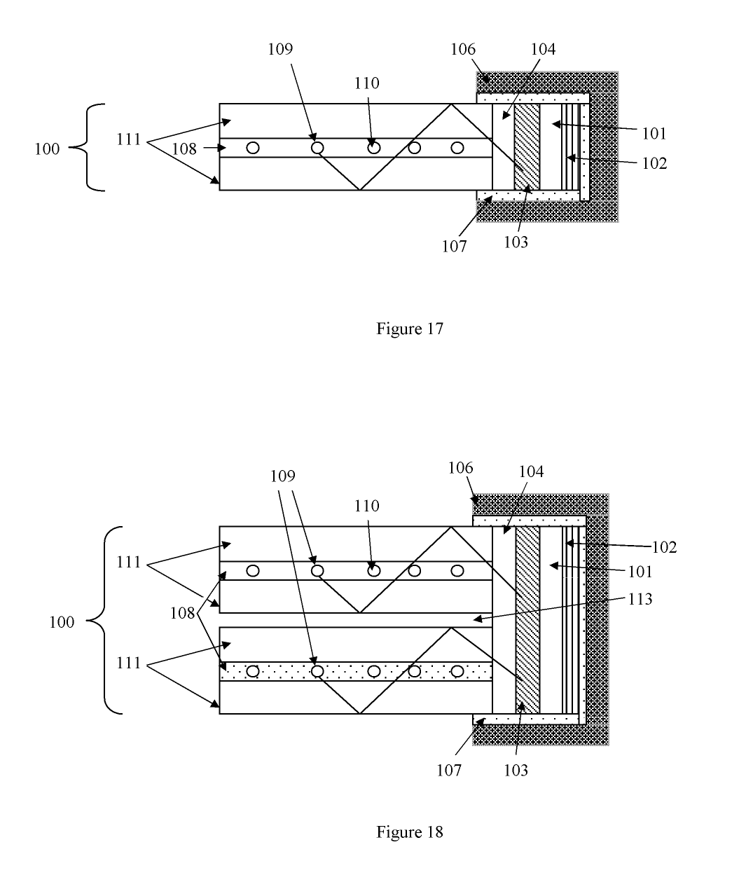

FIG. 17 illustrates a bisected view of an embodiment of a packaged luminescent solar concentrator panel comprising a luminescent solar concentrator 100, a rigid base 102, and solar cells 103 to form a rigid structure. In some embodiments, the solar cells are mounted to the rigid base using a thermally conductive adhesive 101, and the edge of the luminescent solar concentrator 100 is mounted to the light incident side of the solar cell 103 using a transparent adhesive 104. In some embodiments, a frame 106 encapsulates portions of the device to prevent moisture ingress. In some embodiments, as shown, a low refractive index adhesive 107 is used to seal the gaps between the frame and the rigid base/solar cell/LSC assembly. In some embodiments, as shown, the luminescent solar concentrator 100 comprises multiple glass or polymer layers 111 and a single wavelength conversion layer 108. In some embodiments, as shown, the glass or polymer layers can form the top and bottom surfaces of the luminescent solar concentrator. In some embodiments, an incident photon 109 of a first wavelength enters the wavelength conversion layer, and is absorbed by the at least one chromophore compound 110 and re-emitted at a second wavelength which is different than the first, and is then internally reflected and refracted until it reaches the edges where a solar cell 103 is mounted, and is absorbed by the photoelectric conversion layer of the solar cell, and converted into electricity.

FIG. 18 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells are mounted to the rigid base using a thermally conductive adhesive 101. In some embodiments, as shown, the edge of the luminescent solar concentrator 100 is mounted to the light incident side of the solar cell 103 using a transparent adhesive 104, with a frame 106 encapsulation to prevent moisture ingress. In some embodiments, as shown, a low refractive index adhesive 107 is used to seal the gaps between the frame and the rigid base/solar cell/LSC assembly. In some embodiments, the luminescent solar concentrator 100 comprises multiple glass or polymer layers 111 (e.g., two, three, four, five, or more) and multiple wavelength conversion layers 108 (e.g., two, three, four, five, or more) which can be stacked in any order in alternating fashion or otherwise. In some embodiments, incident photons 109 of various wavelengths enter the luminescent solar concentrator and pass through one or several glass or polymer layer(s) and may pass through the wavelength conversion layers. In some embodiments, the wavelength conversion layers are each designed to absorb photons at a different wavelength range, as determined by the chromophore compounds 110, and the chromophore compounds absorb photons of a first wavelength and re-emit them at a second, different wavelength. In some embodiments, the photon reflection path after emission from the wavelength conversion layers is defined by gaps 113 (e.g., containing air, vacuum, gas, fluid, etc.) separating adjacent glass or polymer plates, and photons are internally reflected and refracted within their defined path until they reach the edges where a solar cell 103 is mounted, and are absorbed by the photoelectric conversion layer of the solar cell, and converted into electricity.

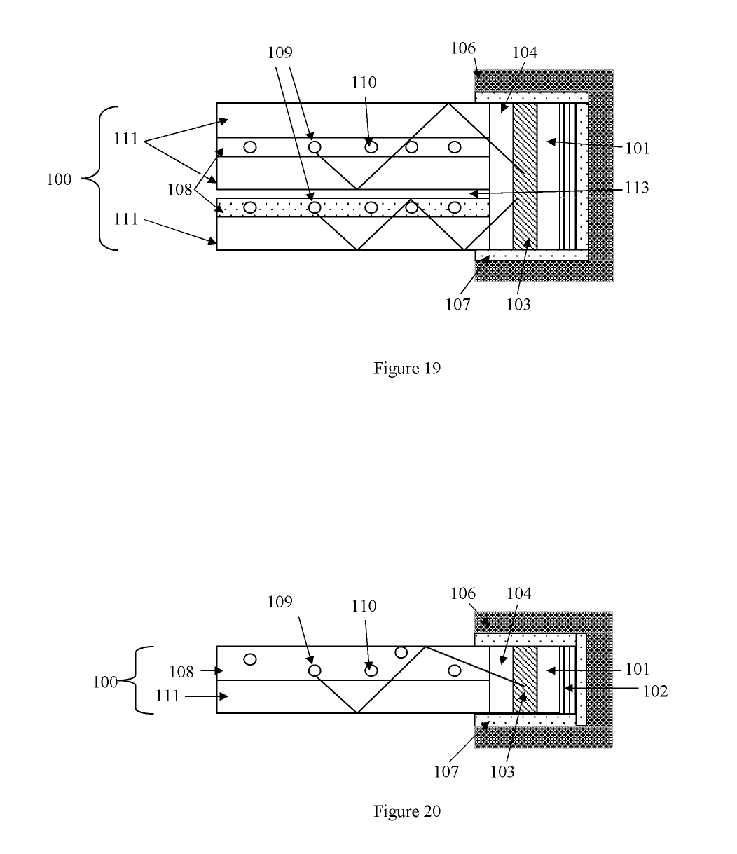

FIG. 19 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells 103 are mounted to the rigid base using a thermally conductive adhesive 101. In some embodiments, as shown, the edge of the luminescent solar concentrator 100 is mounted to the light incident side of the solar cell 103 using a transparent adhesive 104, with a frame 106 encapsulation to prevent moisture ingress. In some embodiments, as shown, a low refractive index adhesive 107 is used to seal the gaps between the frame and the rigid base/solar cell/LSC assembly. In some embodiments, the luminescent solar concentrator 100 comprises multiple glass or polymer layers 111 and multiple wavelength conversion layers 108. In some embodiments, as shown, incident photons 109 of various wavelengths enter the luminescent solar concentrator 100 and pass through one or several glass or polymer layer(s) 111 and may pass through the wavelength conversion layers 108. In some embodiments, the wavelength conversion layers 108 are each designed to absorb photons at a different wavelength range, as determined by the chromophore compounds 110, and the chromophore compounds absorb photons of a first wavelength and re-emit them at a second, different wavelength, wherein the photon reflection path after emission from the wavelength conversion layers 108 is defined by gaps 113 separating adjacent glass or polymer plates. In some embodiments, photons are internally reflected and refracted within their defined path until they reach the edges where a solar cell 103 is mounted, and are absorbed by the photoelectric conversion layer of the solar cell, and converted into electricity.

FIG. 20 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells 103 are mounted to the rigid base 102 using a thermally conductive adhesive 101, and the edge of the luminescent solar concentrator 100 is mounted to the light incident side of the solar cell using a transparent adhesive 104. In some embodiments, as shown, a frame 106 is used for encapsulation to prevent moisture ingress. In some embodiments, as shown, a low refractive index adhesive 107 is used to seal the gaps between the frame and the rigid base/solar cell/LSC assembly. In some embodiments, as shown, the luminescent solar concentrator comprises a glass or polymer layer 111 below (pictured) or above (not pictured) a wavelength conversion layer 108. In some embodiments, as shown, an incident photon 109 of a first wavelength enters the wavelength conversion layer 108, and is absorbed by the at least one chromophore compound 110. In some embodiments, the chromophore is re-emitted at a second wavelength which is different than the first. In some embodiments, the photon (whether re-emitted or as initially absorbed) is internally reflected and refracted until it reaches the edges where a solar cell 103 is mounted, and is absorbed by the photoelectric conversion layer of the solar cell, and converted into electricity.

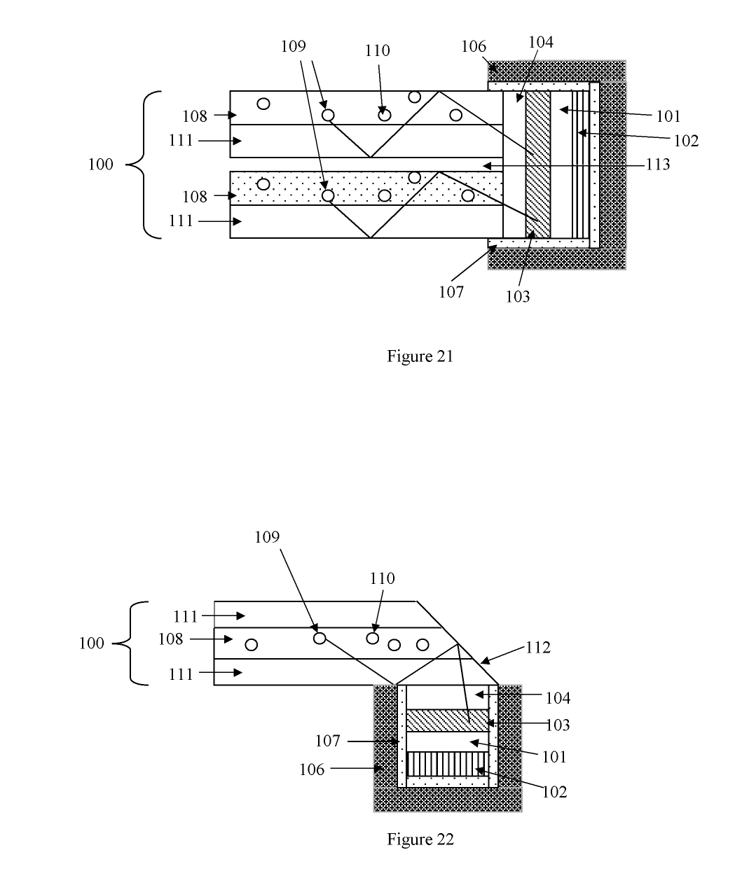

FIG. 21 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells 103 are mounted to the rigid base 102 using a thermally conductive adhesive 101. In some embodiments, as shown, the edge of the luminescent solar concentrator 100 is mounted to the light incident side of the solar cell using a transparent adhesive 104. In some embodiments, as shown, a frame 106 is used to encapsulate at least a portion of the rigid base/solar cell/LSC assembly to prevent moisture ingress, and a low refractive index adhesive 107 is used to seal the gaps between the frame and the rigid base/solar cell/LSC assembly. In some embodiments, as shown, the luminescent solar concentrator 100 comprises multiple glass or polymer layers 111 and multiple wavelength conversion layers 108. In some embodiments, incident photons 109 of various wavelengths enter the luminescent solar concentrator 100. In some embodiments, the photons pass through one or several glass or polymer layer(s) and may pass through the wavelength conversion layers 108. In some embodiments, the wavelength conversion layers 108 are each designed to absorb photons at a different wavelength range, as determined by the chromophore compounds 110. In some embodiments, the chromophore compounds 110 absorb photons of a first wavelength and re-emit them at a second, different wavelength. In some embodiments, the photon reflection path after emission from the wavelength conversion layers is defined by gaps 113 separating adjacent glass or polymer plates. In some embodiments, photons are internally reflected and refracted within their defined path until they reach the edges where a solar cell 103 is mounted. In some embodiments, the photons are absorbed by the photoelectric conversion layer of the solar cell, and converted into electricity.

FIG. 22 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells 103 are mounted to the rigid base 102 using a thermally conductive adhesive 101. In some embodiments, as shown, the rigid base/solar cell assembly are mounted onto the luminescent solar concentrator 100 using a transparent adhesive 104, on the edge of the major planar surface, with a frame 106 encapsulation to prevent moisture ingress. In some embodiments, as shown, a low refractive index adhesive 107 is used to seal the gaps between the frame and the rigid base/solar cell/LSC assembly. In some embodiments, as shown, the luminescent solar concentrator is angled with a corner. In some embodiments, as shown, the corner of the luminescent solar concentrator 100 is ground and polished at an angle of about 30 to about 60 degrees (or about 10 to about 30 degrees, about 30 to about 60 degrees or about 60 to about 80 degrees), and a mirror surface 112 is applied to reflect the photons into the solar cell. In some embodiments, the luminescent solar concentrator 100 comprises multiple glass or polymer layers 111 and a wavelength conversion layer 108. In some embodiments, an incident photon 109 of a first wavelength enters the wavelength conversion layer 100, and is absorbed by the at least one chromophore compound 110. In some embodiments, the photon is re-emitted at a second wavelength which is different than the first, and is then internally reflected and refracted until it reaches the portion of the surface where a solar cell 103 is mounted. In some embodiments, the photon is absorbed by the photoelectric conversion layer of the solar cell, and converted into electricity.

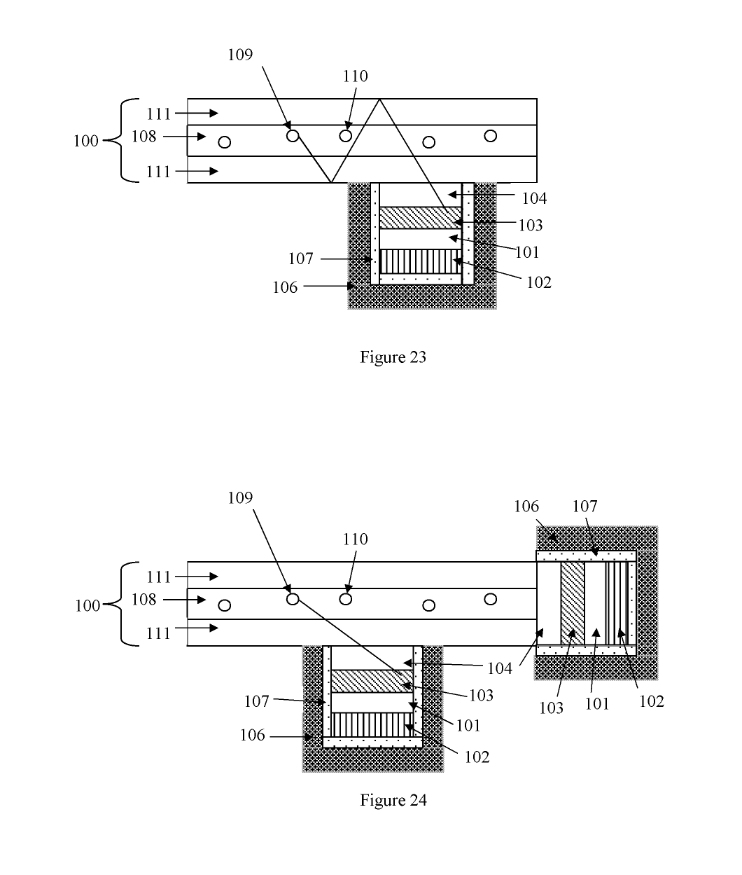

FIG. 23 illustrates a bisected view of an embodiment of a large area packaged luminescent solar concentrator panel comprising a luminescent solar concentrator 100, a rigid base 102, and solar cells 103 to form a rigid structure. In some embodiments, as shown, the solar cells are mounted to the rigid base using a thermally conductive adhesive 101. In some embodiments, as shown, the rigid base/solar cell assembly are mounted onto the luminescent solar concentrator using a transparent adhesive 104, on the back of the major planar surface. In some embodiments, as shown, a frame 106 encapsulates the rigid base to prevent moisture ingress. In some embodiments, as shown, a low refractive index adhesive 107 is used to seal the gaps between the frame and the rigid base/solar cell/LSC assembly. In some embodiments, as shown, the luminescent solar concentrator comprises multiple glass or polymer layers 111 and a wavelength conversion layer 108. In some embodiments, an incident photon 109 of a first wavelength enters the wavelength conversion layer, and is absorbed by the at least one chromophore compound 110 and re-emitted at a second wavelength which is different than the first. In some embodiments, photons are internally reflected and refracted until they reach the portion of the surface where a solar cell 103 is mounted. In some embodiments, photons are absorbed by the photoelectric conversion layer of the solar cell and are converted into electricity.

FIG. 24 illustrates a bisected view of an embodiment of a large area packaged luminescent solar concentrator panel comprising a luminescent solar concentrator 100, a rigid base 102, and solar cells 103 to form a rigid structure. In some embodiments, as shown, the solar cells 103 are mounted to the rigid base using a thermally conductive adhesive 101. In some embodiments, as shown, the rigid base/solar cell assembly are mounted onto the luminescent solar concentrator 100 using a transparent adhesive 104, on both the back of the major planar surface and the edge surface, with a frame 106 encapsulation to prevent moisture ingress, and a low refractive index adhesive 107 is used to seal the gaps between the frame and the rigid base/solar cell/LSC assembly. In some embodiments, as shown, the luminescent solar concentrator 100 comprises multiple glass or polymer layers 111 and a wavelength conversion layer 108, and an incident photon 109 of a first wavelength enters the wavelength conversion layer and is absorbed by the at least one chromophore compound 110. In some embodiments, as shown, the absorbed photon is re-emitted from the chromophore at a second wavelength which is different than the first. In some embodiments, photons are then internally reflected and refracted until they reach the portion of the surface where a solar cell 103 is mounted. In some embodiments, photons are absorbed by the photoelectric conversion layer of the solar cell 103 and are converted into electricity.

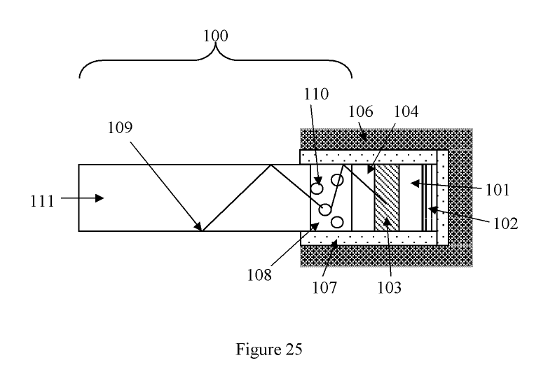

FIG. 25 illustrates a bisected view of an embodiment of a packaged luminescent solar concentrator panel comprising a luminescent solar concentrator 100, a rigid base 102, and solar cells 103 to form a rigid structure. In some embodiments, as shown, the solar cells 103 are mounted to the rigid base using a thermally conductive adhesive 101. In some embodiments, as shown, the edge of the luminescent solar concentrator 100 is mounted to the light incident side of the solar cell 103 using a transparent adhesive 104, with a frame 106 encapsulation to prevent moisture ingress, and a low refractive index adhesive 107 is used to seal the gaps between the frame and the rigid base/solar cell/LSC assembly. In some embodiments, the luminescent solar concentrator comprises a glass or polymer layer 111 and a single wavelength conversion layer 108, and an incident photon 109 of a first wavelength enters the wavelength conversion layer 108, and is absorbed by the at least one chromophore compound 110 and re-emitted at a second wavelength which is different than the first, and is then internally reflected and refracted until it reaches the edges where a solar cell 103 is mounted, and is absorbed by the photoelectric conversion layer of the solar cell, and converted into electricity.

A chromophore compound, sometimes referred to as a luminescent dye or fluorescent dye, is a compound that absorbs photons of a particular wavelength or wavelength range, and re-emits the photon at a different wavelength or wavelength range. Chromophores used in film media can greatly enhance the performance of solar cells and photovoltaic devices. However, such devices are often exposed to extreme environmental conditions for long periods of time, e.g., 20 plus years. As such, maintaining the stability of the chromophore over a long period of time is important.

Chromophores can be up-converting or down-converting. In some embodiments, at least one of the chromophores in the at least one wavelength conversion layer may be an up-conversion chromophore, meaning a chromophore that converts photons from lower energy (long wavelengths) to higher energy (short wavelengths). Up-conversion dyes may include rare earth materials which have been found to absorb photons of wavelengths in the infrared (IR) region, ˜975 nm, and re-emit in the visible region (400-700 nm), for example, Yb³⁺, Tm³⁺, Er³⁺, Ho³⁺, and NaYF⁴. Additional up-conversion materials are described in U.S. Pat. Nos. 6,654,161, and 6,139,210, and in the Indian Journal of Pure and Applied Physics, volume 33, pages 169-178, (1995), which are hereby incorporated by reference in their entirety. In some embodiments, at least one of the chromophores is a down-shifting chromophore, meaning a chromophore that converts photons of high energy (short wavelengths) into lower energy (long wavelengths). In some embodiments, the down-shifting chromophore may independently be a derivative of perylene, benzotriazole, benzothiadiazole, and/or combinations thereof, as are described in U.S. Provisional Patent Application Nos. 61/430,053, 61/485,093, 61/539,392, 61/749,225, and U.S. patent application Ser. Nos. 13/626,679 and 13/978,370, which are hereby incorporated by reference in their entireties. In some embodiments, the wavelength conversion layers comprise both an up-conversion chromophore and at least one down-shifting chromophore.

In some embodiments, the following structure can be used as a chromophore:

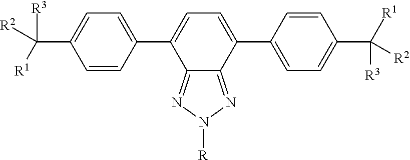

wherein R, R¹, R², R³ are alkyl groups (the same or different). As used herein, the term “alkyl” refers to a branched or straight fully saturated acyclic aliphatic hydrocarbon group (i.e. composed of carbon and hydrogen containing no double or triple bonds). Alkyls include, but are not limited to, methyl, ethyl, propyl, isopropyl, butyl, isobutyl, tertiary butyl, pentyl, hexyl, heptyl, octyl, nonyl, decyl, undecyl, dodecyl, and the like.

In some embodiments, the wavelength conversion layer comprises an optically transparent polymer matrix and at least one chromophore. In some embodiments, the wavelength conversion layer comprises two or more different chromophores. In some embodiments, the wavelength conversion layer can be fabricated by (i) preparing a polymer solution with dissolved polymer powder in a solvent, such as cyclopentanone, dioxane, tetrachloroethylene (TCE), etc., at a predetermined ratio; (ii) preparing a chromophore containing a polymer mixture by mixing the polymer solution with the at least one chromophore at a predetermined weight ratio to obtain a chromophore-containing polymer solution, (iii) forming the chromophore/polymer thin film by directly casting the chromophore-containing polymer solution onto a glass substrate, then heat treating the substrate from room temperature up to 100° C. in 2 hours, completely removing the remaining solvent by further vacuum heating at 130° C. overnight, and (iv) peeling off the chromophore/polymer thin film under the water and then drying out the free-standing polymer film before use; (v) the film thickness can be controlled from 0.1 μm˜1 mm by varying the chromophore/polymer solution concentration and evaporation speed.

In some embodiments, the chromophore is configured to convert incoming photons of a first wavelength to a different second wavelength. Various types of chromophores can be independently included in the at least one wavelength conversion layer. In some embodiments of the inventions, at least one of the chromophores is an organic dye. In some embodiments of the inventions, at least one of the chromophores is selected from perylene derivative dyes, benzotriazole derivative dyes, benzothiadiazole derivative dyes, and combinations thereof.

In some embodiments, the wavelength conversion layer of the luminescent solar concentrator further comprises one or multiple sensitizers. In some embodiments, the sensitizer comprises nanoparticles, nanometals, nanowires, or carbon nanotubes. In some embodiments, the sensitizer comprises a fullerene. In some embodiments, the fullerene is selected from the group consisting of optionally substituted C₆₀, optionally substituted C₇₀, optionally substituted C₈₄, optionally substituted single-wall carbon nanotube, and optionally substituted multi-wall carbon nanotube. In some embodiments, the fullerene is selected from the group consisting of [6,6]-phenyl-C₆₁-butyricacid-methylester, [6,6]-phenyl-C₇₁-butyricacid-methylester, and [6,6]-phenyl-C₈₅-butyricacid-methylester. In some embodiments, the sensitizer is selected from the group consisting of optionally substituted phthalocyanine, optionally substituted perylene, optionally substituted porphyrin, and optionally substituted terrylene. In some embodiments, the wavelength conversion layer of the structure further comprises a combination of sensitizers, wherein the combination of sensitizers is selected from the group consisting of optionally substituted fullerenes, optionally substituted phthalocyanines, optionally substituted perylenes, optionally substituted porphyrins, and optionally substituted terrylenes.

In some embodiments, the at least one wavelength conversion layer comprises the sensitizer in an amount in the range of about 0.01% to about 5%, by weight based on the total weight of the composition.

In some embodiments, the at least one wavelength conversion layer further comprises one or multiple plasticizers. In some embodiments, the plasticizer is selected from N-alkyl carbazole derivatives and triphenylamine derivatives.

In some embodiments, the composition of the at least one wavelength conversion layer further comprises an antioxidant which may act to prevent additional degradation of the chromophore compounds.

In some embodiments, additional materials may be used in the packaged luminescent solar concentrator panel, such as glass plates, polymer layers, or reflective mirror layers. The materials may be used to encapsulate the wavelength conversion layer or layers, or they may be used to protect or encapsulate both the solar cell and wavelength conversion layer(s). In some embodiments, glass plates selected from low iron glass, borosilicate glass, or soda-lime glass, may be used in the module. In some embodiments, the composition of the glass plate or polymer layers may also further comprise a strong UV absorber to block harmful high energy radiation into the solar cell or into the wavelength conversion layer.

In some embodiments of the panel, additional materials or layers may be used such as edge sealing tape, polymer materials, or adhesive layers to adhere additional layers to the system. In some embodiments, the panel further comprises an additional polymer layer containing a UV absorber.

In some embodiments of the panel, multiple types of photovoltaic devices may be used within the panel and may be independently selected and mounted to the frame according to the emission wavelength of the wavelength conversion layer, to provide the highest possible photoelectric conversion efficiency.

Other layers may also be included to further enhance the photoelectric conversion efficiency of solar modules. For example, the luminescent solar concentrator may additionally have at least one microstructured layer, which is designed to further enhance the solar harvesting efficiency of solar modules by decreasing the loss of photons to the environment (see U.S. Provisional Patent Application No. 61/555,799, which is hereby incorporated by reference). A layer with various microstructures on the surface (i.e. pyramids or cones) may increase internal reflection and refraction of the photons into the photoelectric conversion layer of the solar cell, further enhancing the solar harvesting efficiency of the device.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the examples which follow.

### EXAMPLES

The embodiments will be explained with respect to certain embodiments which are not intended to limit the present invention. Further, in the present disclosure where conditions and/or structures are not specified, the skilled artisan in the art can readily provide such conditions and/or structures, in view of the present disclosure, as a matter of routine experimentation.

### Synthesis of Chromophore Compounds

### Compound 1

Synthesis of Compound 1 was performed according to the following scheme:

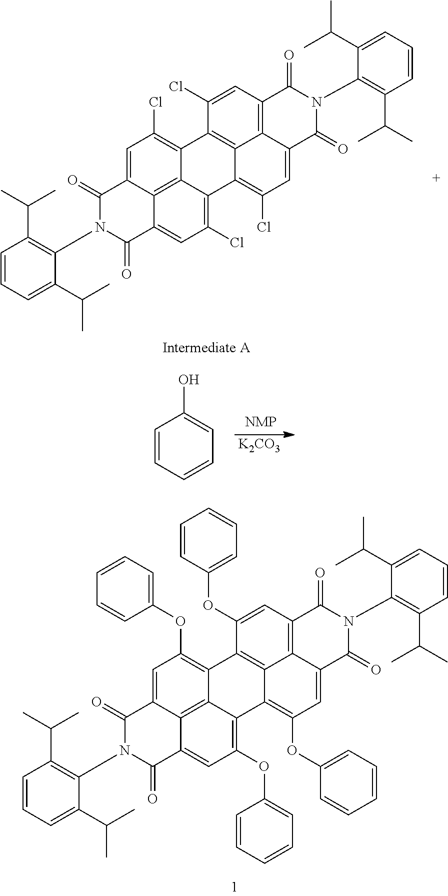

A mixture of 1.89 g of Intermediate A, 1.05 g of phenol, 40 ml of N-methylpyrrolidone (NMP), and 1.23 g of K₂CO₃ were added together under an Argon atmosphere and heated to 132° C. overnight. Then, the reaction mixture was poured into 1 N hydrochloric acid solution, which caused precipitation of the products. The precipitates were filtered out, washed with water, and dried in oven. The crude product was purified by column chromatography on silica gel with dichloromethane/hexane (v/v, 3:2) as eluent to give Compound 1 as a red solid (0.82 g, 34%). UV-vis spectrum (PVB): λₘₐₓ=574 nm. Fluorimetry (PVB): λₘₐₓ=603 nm.

### Compound 2

Synthesis of Compound 2 was performed according to the following scheme:

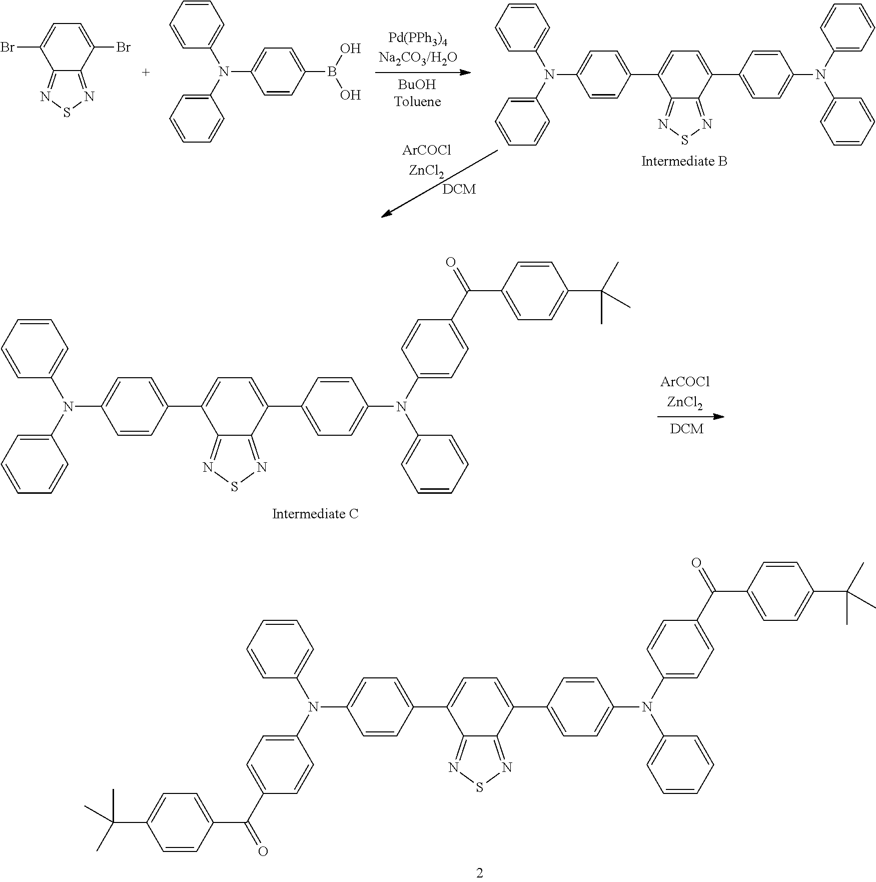

A mixture of 4,7-dibromobenzo[2,1,3]thiadiazole (13.2 g, 45 mmol), 4-(N,N-diphenylamino)phenylboronic acid (30.0 g, 104 mmol), a solution of sodium carbonate (21.2 g, 200 mmol) in water (80 mL), tetrakis(triphenylphosphine)palladium(0) (5.0 g, 4.3 mmol), n-butanol (800 mL), and toluene (400 mL) was stirred under argon and heated at 100° C. for 20 hours. After cooling to room temperature, the mixture was diluted with water (600 mL) and stirred for 2 hours. Finally, the reaction mixture was extracted with toluene (2 L), and the volatiles were removed under reduced pressure. The residue was chromatographed using silica gel and hexane/dichloromethane (1:1) as an eluent to give 26.96 g (43.3 mmol, 96%) of Intermediate B (4,7-bis[(N,N-diphenylamino)phenyl]benzo[2,1,3]thiadiazole).

To a solution of Intermediate B (22.0 g, 35.3 mmol) in dichloromethane (800 mL) stirred under argon and cooled in an ice/water bath were added in small portions 4-t-butylbenzoyl chloride (97.4 mL, 500 mmol) and 1M solution of zinc chloride in ethyl ether (700 mL, 700 mmol). The obtained mixture was stirred and heated at 44° C. for 68 hours. The reaction mixture was poured onto crushed ice (2 kg), stirred, treated with saturated sodium carbonate to pH 8, diluted with dichloromethane (2 L) and filtered through a frit-glass funnel under atmospheric pressure. The dichloromethane layer was separated, dried over magnesium sulfate, and the solvent was evaporated. Column chromatography of the residue (silica gel, hexane/dichloromethane/ethyl acetate, 48:50:2) followed by recrystallization from ethanol gave pure luminescent dye Intermediate C as the first fraction, 7.72 g (28%). ¹H NMR (400 MHz, CDCl₃): δ 7.94 (d, 2H, J=7.3 Hz), 7.87 (d, 2H, J=7.7 Hz), 7.74 (m, 6H), 7.47 (d, 2H, J=7.3 Hz), 7.36 (t, 2H, J=7.3 Hz), 7.31 (d, 2H, J=7.3 Hz), 7.27 (m, 6H), 7.19 (m, 7H), 7.13 (d, 2H, J=7.7 Hz), 7.06 (t, 2H, J=7.3 Hz), 1.35 (s, 9H). UV-vis spectrum: λₘₐₓ=448 nm (dichloromethane), 456 nm (PVB film). Fluorimetry: λₘₐₓ=618 nm (dichloromethane), 562 nm (PVB film).

The second fraction gave luminescent dye Compound 2, 12.35 g (37% yield). ¹H NMR (400 MHz, CDCl₃): δ 7.95 (d, 4H, J=8.4 Hz), 7.79-7.73 (m, 10H), 7.48 (d, 4H, J=7.7 Hz), 7.36 (t, 4H, J=7.7 Hz), 7.31 (d, 4H, J=8.4 Hz), 7.25 (d, 4H, J=7.7 Hz), 7.18 (t, J=7.3, 2H, Ph), 7.14 (d, 4H, J=8.8 Hz), 1.35 (s, 18H). UV-vis spectrum: λₘₐₓ=437 nm (dichloromethane), 455 nm (PVB film). Fluorimetry: λₘₐₓ=607 nm (dichloromethane), 547 nm (PVB film).

### Compound 3

Synthesis of Compound 3 was performed according to the following scheme:

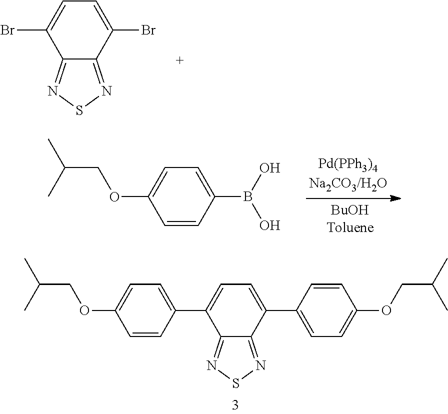 [SMILES: Brc1ccc(Br)c2nsnc12 ; CC(C)COc1ccc(B(O)O)cc1 ; CC(C)COc1ccc(-c2ccc(-c3ccc(OCC(C)C)cc3)c3nsnc23)cc1]

A mixture of 4,7-dibromobenzo[2,1,3]thiadiazole (10.0 g, 34 mmol), 4-isobutoxyphenylboronic acid (15.0 g, 77 mmol), a solution of sodium carbonate (10.6 g, 100 mmol) in water (40 mL), tetrakis(triphenylphosphine)palladium(0) (5.0 g, 4.3 mmol), n-butanol (200 mL), and toluene (100 mL) was stirred under argon and heated at 100° C. for 24 hours. After cooling, the mixture was poured into water (1 L), diluted with toluene (500 mL) and stirred for 1 hour. The organic phase was separated, washed with water (200 mL), and the volatiles were removed under reduced pressure. The crude product was purified by column chromatography (silica gel, hexane/dichloromethane, 1:1) and recrystallization from ethanol to give chromophore Compound 3, 12.71 g (86% yield). ¹H NMR (400 MHz, CDCl₃): δ 7.90 (d, 4H, J=8.8 Hz), 7.71 (s, 2H), 7.07 (d, 4H, J=9.2 Hz), 3.81 (d, 4H, J=6.6 Hz), 2.14 (m, 2H), 1.05 (d, 12H, J=6.6 Hz). UV-vis spectrum: λₘₐₓ=408 nm (dichloromethane), 416 nm (PVB film). Fluorimetry: λₘₐₓ=548 nm (dichloromethane), 515 nm (PVB film).

### Example 1

In some embodiments, a wavelength conversion film 100, comprising at least one chromophore, and an optically transparent polymer matrix, is fabricated by (i) preparing a 20 wt % EVA-poly ethylene vinyl acetate (EVA) (PV1400Z from Dupont) polymer solution with dissolved polymer powder in cyclopentanone; (ii) preparing a chromophore containing a EVA matrix by mixing the EVA polymer solution with the synthesized Compound 1 at a weight ratio (Compound 1/EVA) of 0.3 wt %, to obtain a chromophore-containing polymer solution; (iii) stirring the solution for approximately 30 minutes; (iv) then forming the chromophore/polymer film by directly drop casting the dye-containing polymer solution onto a substrate, then allowing the film to dry at room temperature overnight followed by heat treating the film at 60° C. under vacuum for 10 minutes, to completely remove the remaining solvent, and (v) hot pressing the dry composition under vacuum to form a bubble free film with film thickness ranging from approximately 200 μm to 600 μm.

After preparation of the wavelength conversion film, the film was then laminated between two low iron glass plates to form the luminescent solar concentrator, similar to the embodiment shown in FIG. 7. The glass plates were approximately 2 inch×2 inch×2 mm, with the major planar surface area dimensions of 2 inches by 2 inches.

The packaging of the LSC device was then performed according to the following procedure: (i) place a thermally conductive tape (MASTER BOND EP21TCHT-1, a two component, thermally conductive epoxy from Master Bond Inc.) on top of an aluminum rigid base of dimensions 25 mm×2 mm (ii) then, place Solar Cells of 6 mm×25 mm (from IXY Solar, with a conversion efficiency of ˜17%) on top of the MASTER BOND EP21TCHT-1, as shown in FIG. 1, and gently push the solar cell panel down to remove air bubbles, (iii) cure the MASTER BOND EP21TCHT-1 at room temperature for overnight, (iv) then put UV Epoxy (Norland optical adhesive 68T from Norland Products Inc.) on top of the solar cell, (v) for devices larger than 4 inch×4 inch, use an LSC mounting rack to hold the LSC device vertically above the aluminum rigid base and solar cell panel assembly such that the edge of the LSC device is aligned with the solar cell panel, as shown in FIG. 2, (vi) gently press the LSC device down onto the UV Epoxy on the face of the solar cell panel and remove all air bubbles, (vii) pre-cure the UV epoxy using ELC-405 light curing system from Electro-Lite Corporation, curing time is 90 seconds each side and 180 seconds total, (viii) cure UV epoxy using Loctite® Zeta® 7411 UV Flood Curing System, curing time is 3 minutes each side and 6 minutes total, (ix) repeat steps (i) to (viii) for each of the other 3 sides. Once all sides of the LSC device have been mounted to the aluminum rigid base/solar panel assembly, use four U-shape aluminum frames to cover the aluminum rigid base/solar cell panel/LSC assembly on the four sides similar to the device shown in FIG. 17. The MASTER BOND EP21TCHT-1 is used between the aluminum frame sides and aluminum rigid base/solar panel/LSC assembly to seal the solar cells in the package and also to provide good heat conductivity.

### Measurement of the Efficiency

The packaged luminescent solar concentrator panel photoelectric conversion efficiency was measured by a Newport 300W full spectrum solar simulator system. The light intensity was adjusted to one sun (AM1.5G) by a 2 cm×2 cm calibrated reference monocrystalline silicon solar cell. Then the I-V characterization of the packaged luminenscent solar concentrator panel was performed under the same irradiation and its efficiency is calculated by the Newport software program which is installed in the simulator. The c-Si solar cells used in this study have an efficiency η_{cell} of 17%, which is similar to the efficiency level achieved in most commercially available c-Si cells. After determining the stand alone efficiency of the cells, the cells were mounted to the packaged luminescent solar concentrator panel as described in Example 1. The solar cell efficiency of the packaged luminescent solar concentrator panel η_{cell+LSC} was measured again under same one sun exposure, and determined to be 5.0%.

### Example 2

Example 2 is synthesized using the same method as given in Example 1, except that a 4 in×4 inch device was made, and Chromophore Compound 2 was used instead of Chromophore Compound 1. The solar cell efficiency of the packaged luminescent solar concentrator panel η_{cell+LSC} was measured under same one sun exposure, and determined to be 4.5%.

### Example 3

Example 3 is synthesized using the same method as given in Example 1, except that a 6 in×6 inch device was made, solar cells of dimensions 10 mm×150 mm were used, and a mixture of Chromophore Compounds 1, 2, and 3 were used in the wavelength conversion layer. The solar cell efficiency of the packaged luminescent solar concentrator panel η_{cell+LSC} was measured under same one sun exposure, and determined to be 3.5%.

### Example 4

Example 4 is synthesized using the same method as given in Example 1, except that a 12 in×12 inch device was made, solar cells of dimensions 10 mm×150 mm were used, and a mixture of Chromophore Compounds 1, 2, and 3 were used in the wavelength conversion layer. The solar cell efficiency of the packaged luminescent solar concentrator panel η_{cell+LSC} was measured under same one sun exposure, and determined to be 4.0%.

As illustrated by the examples above, the packaged luminescent solar concentrator panels, as disclosed herein, provide a functional package or panel that can readily be applied to buildings or structures to generate electricity. The packaged luminescent solar concentrator panel collects both direct and diffuse light and provides highly efficient and low cost solar harvesting solutions by using a minimal amount of expensive solar cells. The packaged luminescent solar concentrator panel is well suited for building integrated photovoltaics such as sunroofs, skylights, and facades of commercial and residential buildings. All prepared examples showed efficiencies of 3.0% or greater. Due to the high cost of Silicon solar cells, packaged luminescent solar concentrators, as described herein, may provide a significant improvement in the price per watt of electricity generated by these devices.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

It will be understood by those of skill in the art that numerous and various modifications can be made without departing from the spirit of the present invention. Therefore, it should be clearly understood that the forms of the present invention are illustrative only and are not intended to limit the scope of the present invention.

In summary, various embodiments and examples of packaged luminescent solar concentrator panels have been disclosed. Although the packaged luminescent solar concentrator panels have been disclosed in the context of those embodiments and examples, it will be understood by those skilled in the art that this disclosure extends beyond the specifically disclosed embodiments to other alternative embodiments and/or other uses of the embodiments, as well as to certain modifications and equivalents thereof. For example, some embodiments can be configured to be used with other types of packaged luminescent solar concentrator panels or configurations. This disclosure expressly contemplates that various features and aspects of the disclosed embodiments can be combined with, or substituted for, one another. Accordingly, the scope of this disclosure should not be limited by the particular disclosed embodiments described above, but should be determined only by a fair reading of the claims that follow.

1-51. (canceled)

52. A packaged luminescent solar concentrator panel comprising:
a luminescent solar concentrator configured to receive photons from a photon source, the luminescent solar concentrator comprising a wavelength conversion layer, wherein the wavelength conversion layer comprises at least one chromophore; and
a rigid base configured to support the luminescent solar concentrator, wherein the rigid base is disposed over a portion of the luminescent solar concentrator.

53. The packaged luminescent solar concentrator panel of claim 52, wherein the luminescent solar concentrator comprises a top surface that receives the photons from the photon source, a bottom surface, and at least one edge surface extending between the top surface and the bottom surface.

54. The packaged luminescent solar concentrator of claim 53, further comprising at least one photovoltaic device disposed between the luminescent solar concentrator and the rigid base.

55. The packaged luminescent solar concentrator panel of claim 54, wherein the at least one photovoltaic device is mounted to the at least one edge surface of the luminescent solar concentrator.

56. The packaged luminescent solar concentrator panel of claim 54, wherein the at least one photovoltaic device is mounted to the bottom surface of the luminescent solar concentrator.

57. The packaged luminescent solar concentrator panel of claim 56, further comprising a second photovoltaic device mounted to the at least one edge surface of the luminescent solar concentrator.

58. The packaged luminescent solar concentrator of claim 54, wherein the at least one photovoltaic device is mounted to the rigid base with a thermally conductive adhesive.

59. The packaged luminescent solar concentrator of claim 58, wherein the thermally conductive adhesive has a thermal conductivity of about 1 W/mK or greater.

60. The packaged luminescent solar concentrator of claim 54, wherein the luminescent solar concentrator is mounted to the at least one photovoltaic device using a transparent adhesive.

61. The packaged luminescent solar concentrator of claim 60, wherein the transparent adhesive is a material selected from the group consisting of an acrylic polymer, polyethylene terephthalate, polymethyl methacrylate, polyvinyl butyral, ethylene vinyl acetate polymer, ethylene tetrafluoroethylene polymer, polyimide, amorphous polycarbonate, polystyrene, a siloxane sol-gel, polyurethane, and polyacrylate.

62. The packaged luminescent solar concentrator panel of claim 52, wherein the rigid base is a material selected from the group consisting of metal, metal composite, metal alloy, ceramic, and plastic.

63. The packaged luminescent solar concentrator panel of claim 52, wherein the rigid base is a metal selected from the group consisting of aluminum, tin, bronze, steel, iron, and copper.

64. The packaged luminescent solar concentrator panel of claim 52, further comprising a frame, wherein the frame is configured to engage the rigid base.

65. The packaged luminescent solar concentrator panel of claim 64, wherein the frame engages the rigid base and at least a portion of the luminescent solar concentrator.

66. The packaged luminescent solar concentrator panel of claim 64, wherein the frame is two-sided and is configured to engage the rigid base via a first frame side and a second rigid base of a second packaged luminescent solar concentrator panel via a second frame side.

67. The packaged luminescent solar concentrator panel of claim 64, wherein the frame is a material selected from the group consisting of metal, metal composite, metal alloy, polymer, and wood.

68. The packaged luminescent solar concentrator panel of claim 64, wherein the frame and rigid base are adhered together using a low refractive index adhesive.

69. The packaged luminescent solar concentrator panel of claim 53, wherein the luminescent solar concentrator has a perimeter comprising the at least one edge surface, wherein the rigid base surrounds the luminescent solar concentrator by engaging the perimeter of the luminescent solar concentrator.

70. The packaged luminescent solar concentrator panel of claim 52, wherein the luminescent solar concentrator comprises a top surface for receipt of the photons from the photon source, a bottom surface, and four edge surfaces wherein the edge surfaces extending between the top surface and the bottom surface, wherein the four edge surfaces form a perimeter of the luminescent solar concentrator.

71. The packaged luminescent solar concentrator panel of claim 70, wherein the rigid base engages each of the four edge surfaces and engages the luminescent solar concentrator via its perimeter.
